(19) United States
(12) Patent Application Publication
(10) Pub. No.: US 2024/0203631 A1
(43) Pub. Date: Jun. 20, 2024

(54) INDUCTOR COMPONENT

(71) Applicant: Murata Manufacturing Co., Ltd., Kyoto-fu (JP)

(72) Inventors: Takeru OZAWA, Nagaokakyo-shi (JP); Atsushi SEKO, Nagaokakyo-shi (JP); Seiya KIKUCHI, Nagaokakyo-shi (JP)

(73) Assignee: Murata Manufacturing Co., Ltd., Kyoto-fu (JP)

(21) Appl. No.: 18/489,712

(22) Filed: Oct. 18, 2023

(30) Foreign Application Priority Data
Dec. 14, 2022 (JP) 2022-199536

(51) Int. Cl. H01F 17/00; H01F 27/29

(52) U.S. Cl. CPC H01F 17/0013; H01F 27/292

(57) ABSTRACT

An inductor component includes an element body, a coil inside the element body and spirally wound along a coil axial direction, a first outer electrode electrically connected to one end portion of the coil and exposed on a surface of the element body, and a second outer electrode electrically connected to the other end portion of the coil and exposed on the surface of the element body. The element body includes an insulator. The coil is formed by electrically connecting a plurality of coil wires laminated in the coil axial direction. The coil wires include a first coil wire electrically connected to the first outer electrode with at least one first extended wire interposed therebetween, and a dimension of each of the at least one first extended wire in the coil axial direction is smaller than a dimension of the first coil wire in the coil axial direction.

### CROSS-REFERENCE TO RELATED APPLICATION

This application claims benefit of priority to Japanese Patent Application No. 2022-199536, filed Dec. 14, 2022, the entire content of which is incorporated herein by reference.

### BACKGROUND

### Technical Field

The present disclosure relates to an inductor component.

### Background Art

Japanese Patent No. 6787286 discloses a method of manufacturing an inductor component. The method includes a step of preparing an insulating paste having photosensitivity and a conductive paste, the insulating paste containing a filler material made of quartz, a glass material, and a resin material, a step of applying the insulating paste to form a first insulating layer, a step of exposing the first insulating layer to light with a first portion of the first insulating layer shielded from light by a mask, a step of removing the first portion of the first insulating layer to form a groove having a depth of the groove larger than a width of the groove at a position corresponding to the first portion, a step of applying the conductive paste in the groove to form a coil conductor layer in the groove, and a step of applying the insulating paste on the first insulating layer and the coil conductor layer to form a second insulating layer.

### SUMMARY

According to the method of manufacturing the inductor component described in Japanese Patent No. 6787286, since an aspect ratio and a cross-sectional area of the coil conductor layers can be increased, coil characteristics can be improved.

However, as a result of studies by the present inventors, when the inductor component having a coil wire with a large aspect ratio or a large cross-sectional area is to be formed as in Japanese Patent No. 6787286, since a large amount of stress is likely to remain in the vicinity of an extended wire connecting the coil wire and an outer electrode during firing in a manufacturing process, in a case where the aspect ratio or the cross-sectional area of the coil wire is further increased or the inductor component is miniaturized, it is found that interfacial delamination between the extended wire and an element body (insulating layer) is generated with residual stress as a starting point, and as a result, cracks may occur.

Accordingly, the present disclosure provides an inductor component capable of suppressing occurrence of cracks caused by stress remaining in a vicinity of an extended wire during a manufacturing process.

In a first aspect, an inductor component of the present disclosure includes an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body, the element body includes an insulator. The coil is formed by electrically connecting a plurality of coil wires laminated in the coil axial direction. The plurality of coil wires include a first coil wire electrically connected to the first outer electrode with one or a plurality of first extended wires interposed therebetween, and a dimension of each of the one or the plurality of first extended wires in the coil axial direction is smaller than a dimension of the first coil wire in the coil axial direction.

In a second aspect, an inductor component of the present disclosure includes an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body, the element body includes an insulator. The coil is formed by electrically connecting a plurality of coil wires laminated in the coil axial direction. The plurality of coil wires include a first coil wire electrically connected to the first outer electrode with one or a plurality of first extended wires interposed therebetween. When viewed in a length direction orthogonal to the coil axial direction, both end portions of the first extended wire and both end portions of the first outer electrode are displaced from each other in the coil axial direction.

In a third aspect, an inductor component of the present disclosure includes an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body, the element body includes an insulator. The surface of the element body includes a bottom surface perpendicular to the coil axial direction and a top surface facing the bottom surface in the coil axial direction. Each of the first outer electrode and the second outer electrode are exposed so as to be separated from each other at least on the bottom surface of the element body. The coil is formed by electrically connecting a plurality of coil wires laminated in the coil axial direction. The plurality of coil wires include a first coil wire electrically connected to the first outer electrode with one or a plurality of first extended wires interposed therebetween and a second coil wire electrically connected to the second outer electrode with one or a plurality of second extended wires interposed therebetween, the first extended wire is located further toward the top surface side of the element body than the second extended wire in the coil axial direction. When viewed in a length direction orthogonal to the coil axial direction, a minimum distance between an end portion of the first extended wire and an end portion of the first outer electrode is larger than a minimum distance between an end portion of the second extended wire and an end portion of the second outer electrode in a width direction orthogonal to the coil axial direction and to the length direction.

In the inductor component of the present disclosure, when viewed in the coil axial direction, in the path where the coil wire is connected to the outer electrode, the wire that extends toward the outer electrode, while being inclined with respect to the linear portion of the coil wire is defined as the extended wire. In this case, when viewed in the coil axial direction, the coil wire and the extended wire are not present on the same straight line with a connecting portion between the coil wire and the extended wire as a boundary. In a case where a wire corresponding to the extended wire defined as described above is not found when viewed in the coil axial direction, a wire not overlapping a winding portion of the coil when viewed in the coil axial direction (a wire protruding from the winding portion of the coil) is defined as an extended wire.

According to the present disclosure, it is possible to provide the inductor component capable of suppressing the occurrence of cracks due to the stress remaining in the vicinity of the extended wire during the manufacturing process.

### BRIEF DESCRIPTION OF THE DRAWINGS

FIG. 1 is a schematic perspective view illustrating an example of an inductor component according to Embodiment 1 of the present disclosure;

FIG. 2 is a schematic perspective view illustrating an example of an exploded state of the inductor component illustrated in FIG. 1;

FIG. 3 is a schematic sectional view illustrating an example of a cross section along the line segment a1-a2 of the inductor component illustrated in FIG. 1;

FIG. 4 is a schematic perspective view illustrating an example of an inductor component according to Embodiment 2 of the present disclosure;

FIG. 5 is a schematic sectional view illustrating an example of a cross section along the line segment b1-b2 of the inductor component illustrated in FIG. 4;

FIG. 6 is a schematic sectional view illustrating an example of a configuration in which three first extended wires are arranged in a coil axial direction with respect to a configuration illustrated in FIG. 5;

FIG. 7 is a schematic sectional view illustrating an example of a configuration in which four first extended wires are arranged in the coil axial direction with respect to the configuration illustrated in FIG. 6;

FIG. 8 is a schematic sectional view illustrating a modification example of the configuration illustrated in FIG. 5;

FIG. 9 is a schematic sectional view illustrating another modification example of the configuration illustrated in FIG. 5;

FIG. 10 is a schematic sectional view illustrating a modification example of the configuration illustrated in FIG. 6;

FIG. 11 is a schematic sectional view illustrating another modification example of the configuration illustrated in FIG. 6;

FIG. 12 is a schematic sectional view illustrating still another modification example of the configuration illustrated in FIG. 6;

FIG. 13 is a schematic perspective view illustrating an example of an inductor component according to Embodiment 3 of the present disclosure;

FIG. 14 is a schematic sectional view illustrating an example of a cross section along the line segment c1-c2 of the inductor component illustrated in FIG. 13;

FIG. 15 is a schematic sectional view illustrating an example of a cross section along the line segment d1-d2 of the inductor component illustrated in FIG. 13;

FIG. 16 is a schematic perspective view illustrating an example of an inductor component according to Embodiment 4 of the present disclosure;

FIG. 17 is a schematic sectional view illustrating an example of a cross section along the line segment e1-e2 of the inductor component illustrated in FIG. 16;

FIG. 18 is a schematic sectional view illustrating an example of a cross section along the line segment f1-f2 of the inductor component illustrated in FIG. 16;

FIG. 19 is a schematic perspective view illustrating an example of an inductor component according to Embodiment 5 of the present disclosure;

FIG. 20 is a schematic sectional view illustrating an example of a cross section along the line segment g1-g2 of the inductor component illustrated in FIG. 19;

FIG. 21 is a schematic perspective view illustrating an example of an inductor component according to a modification example of Embodiment 5 of the present disclosure;

FIG. 22 is a schematic sectional view illustrating an example of a cross section along the line segment h1-h2 of the inductor component illustrated in FIG. 21;

FIG. 23 is a schematic sectional view illustrating an example of a cross section along the line segment j1-j2 of the inductor component illustrated in FIG. 21;

FIG. 24 is a schematic perspective view illustrating an example of an inductor component according to Embodiment 6 of the present disclosure;

FIG. 25 is a schematic perspective view illustrating an example of an inductor component according to Embodiment 7 of the present disclosure;

FIG. 26 is a schematic sectional view illustrating an example of a cross section along the line segment k1-k2 of the inductor component illustrated in FIG. 25;

FIG. 27 is a schematic perspective view illustrating an example of an inductor component according to Embodiment 8 of the present disclosure;

FIG. 28 is a schematic sectional view illustrating an example of a cross section along the line segment m1-m2 of the inductor component illustrated in FIG. 27; and

FIG. 29 is a schematic sectional view illustrating an example of a cross section along the line segment n1-n2 of the inductor component illustrated in FIG. 27.

### DETAILED DESCRIPTION

Hereinafter, an inductor component of the present disclosure will be described. The present disclosure is not limited to the following configurations, and may be modified as appropriate without departing from the gist of the present disclosure. In addition, the present disclosure also includes a combination of a plurality of individual preferred configurations described below.

Each embodiment described below is an example, and it goes without saying that partial replacement or combination of configurations described in different embodiments is possible. In Embodiment 2 and subsequent embodiments, descriptions of matters common to Embodiment 1 will be omitted, and different points will be mainly described. In particular, similar actions and effects due to similar configurations will not be mentioned sequentially for each embodiment.

In the following description, the term “inductor component of the present disclosure” is simply used, in a case where each embodiment is not particularly distinguished.

The drawings described below are schematic diagrams, and the dimensions, aspect ratios, and the like may differ from an actual product.

In this specification, terms denoting relationships between elements (for example, “parallel”, “perpendicular”, “orthogonal”, and the like) and terms denoting shapes of elements are meant not only for a literal and strict aspect but also for substantially equivalent ranges, for example, a range including a difference of approximately several %.

In a first aspect, an inductor component of the present disclosure includes an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body, the element body includes an insulator, the coil is formed by electrically connecting a plurality of coil wires laminated in the coil axial direction, the plurality of coil wires include a first coil wire electrically connected to the first outer electrode with one or a plurality of first extended wires interposed therebetween, and a dimension of each of the one or the plurality of first extended wires in the coil axial direction is smaller than a dimension of the first coil wire in the coil axial direction.

### Embodiment 1

An example of the first aspect of the inductor component of the present disclosure will be described below as an inductor component according to Embodiment 1 of the present disclosure. In the inductor component according to Embodiment 1 of the present disclosure, a first coil wire is electrically connected to a first outer electrode with one first extended wire interposed therebetween.

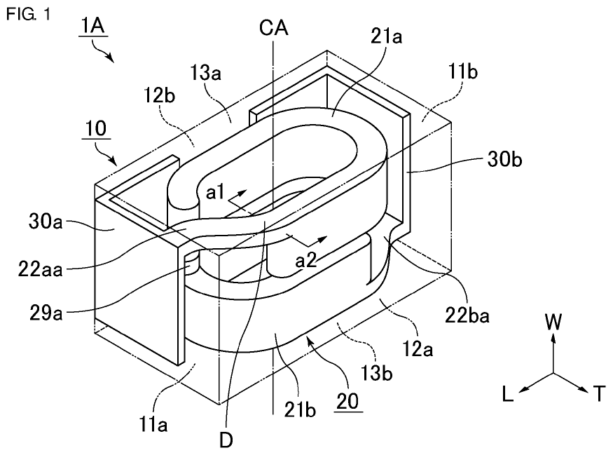

FIG. 1 is a schematic perspective view illustrating an example of the inductor component according to Embodiment 1 of the present disclosure.

An inductor component 1A illustrated in FIG. 1 includes an element body 10, a coil 20, a first outer electrode 30a, and a second outer electrode 30b.

In this specification, each of the length direction, height direction, and width direction is the direction defined by L, T, and W, as illustrated in FIG. 1 and the like. Here, the length direction L, the height direction T, and the width direction W are orthogonal to each other.

As illustrated in FIG. 1, in the inductor component 1A, the surfaces of the element body 10 include an end surface 11a and an end surface 11b facing each other in the length direction L, a top surface 12a and a bottom surface 12b facing each other in the height direction T, and a side surface 13a and a side surface 13b facing each other in the width direction W. In the inductor component 1A, the width direction W is parallel to the coil axial direction of the coil 20. That is, in the inductor component 1A, the surfaces of the element body 10 include the bottom surface 12b parallel to the coil axial direction and the top surface 12a facing the bottom surface 12b in the height direction T orthogonal to the coil axial direction.

In the present embodiment, the coil axial direction is a direction parallel to the width direction W unless otherwise specified.

In the inductor component 1A, the bottom surface 12b of the element body 10 is a mounting surface. More specifically, the bottom surface 12b of the element body 10 is a mounting surface that faces an object to be mounted (for example, substrate) when the inductor component 1A is mounted. Therefore, in the inductor component 1A, the mounting surface of the element body 10, that is, the bottom surface 12b of the element body 10 is parallel to the coil axial direction.

At least one of the surfaces of the element body 10, that is, at least one of the end surface 11a, the end surface 11b, the top surface 12a, the bottom surface 12b, the side surface 13a, and the side surface 13b, may be marked for easy identification of each surface.

The end surface 11a and the end surface 11b of the element body 10 need not be strictly orthogonal to the length direction L. In addition, the top surface 12a and the bottom surface 12b of the element body 10 need not be strictly orthogonal to the height direction T. Furthermore, the side surface 13a and the side surface 13b of the element body 10 need not be strictly orthogonal to the width direction W.

As illustrated in FIG. 1, the element body 10 has, for example, a rectangular parallelepiped shape.

In this specification, the rectangular parallelepiped shape may be any shape that can be considered to be substantially a rectangular parallelepiped shape, and includes, for example, a substantially rectangular parallelepiped shape with rounded corner portions and ridge portions as described later.

In the element body 10, it is preferable that corner portions and ridge portions are rounded. The corner portion of the element body 10 is a portion where three surfaces of the element body 10 intersect. The ridge portion of the element body 10 is a portion where two surfaces of the element body 10 intersect.

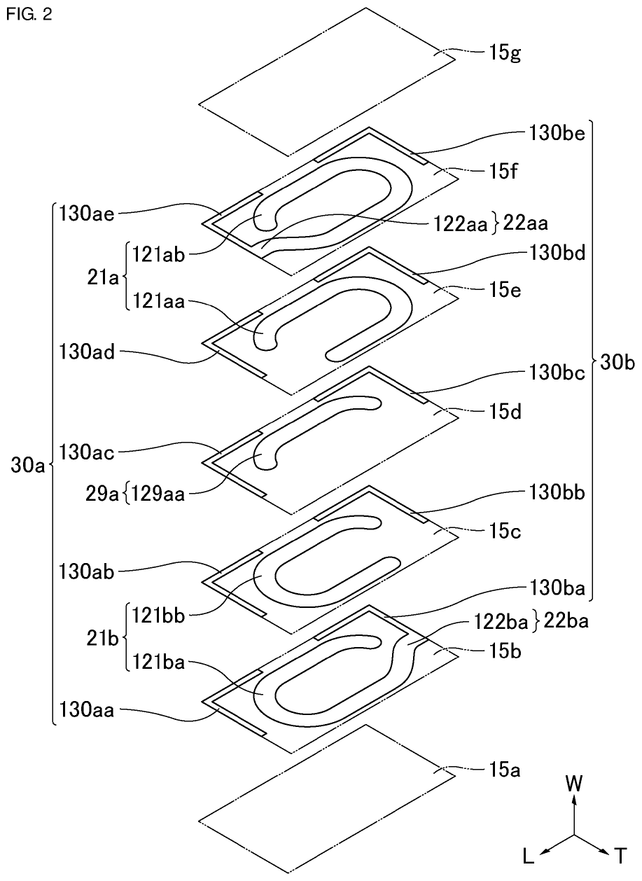

FIG. 2 is a schematic perspective view illustrating an example of an exploded state of the inductor component illustrated in FIG. 1.

The element body 10 includes an insulator. In the example illustrated in FIG. 2, the insulator is formed by laminating a plurality of insulating layers in the coil axial direction.

In the example illustrated in FIG. 2, the plurality of insulating layers include an insulating layer 15a, an insulating layer 15b, an insulating layer 15c, an insulating layer 15d, an insulating layer 15e, an insulating layer 15f, and an insulating layer 15g. The insulating layer 15a, the insulating layer 15b, the insulating layer 15c, the insulating layer 15d, the insulating layer 15e, the insulating layer 15f, and the insulating layer 15g are laminated in order from the side surface 13b side toward the side surface 13a side of the element body 10 in the coil axial direction.

The plurality of insulating layers are integrated, and these boundaries may be unclear.

The plurality of insulating layers may further include at least one other insulating layer in addition to the insulating layers described above. For example, at least one insulating layer may be present between the insulating layer 15a and the insulating layer 15b in the coil axial direction. In addition, at least one insulating layer may be present between the insulating layer 15f and the insulating layer 15g in the coil axial direction.

Examples of insulating materials constituting the insulator (insulating layer) include glass materials containing borosilicate glass as a main component, ceramic materials, organic materials such as epoxy resins, fluororesins, and polymer resins, composite materials such as glass epoxy resins, or the like. As an insulating material, a material having a small dielectric constant and a small dielectric loss is particularly preferable.

The insulating materials constituting the plurality of insulating layers may be the same as each other, may be different from each other, or may be partially different.

The dimensions of the plurality of insulating layers in the coil axial direction may be the same as each other, may be different from each other, or may be partially different.

As illustrated in FIG. 1, the coil 20 is provided inside the element body 10 and is spirally wound along the coil axial direction.

The coil axial direction of the coil 20 is the direction where a coil axis CA of the coil 20 extends, and is parallel to the bottom surface 12b, which is the mounting surface of the element body 10, as described above.

As illustrated in FIGS. 1 and 2, the coil 20 is formed by electrically connecting a plurality of coil wires laminated in the coil axial direction.

In the example illustrated in FIGS. 1 and 2, the plurality of coil wires include a first coil wire 21a and a second coil wire 21b.

The first coil wire 21a is present at the outermost position on the side surface 13a side of the element body 10 in the coil axial direction among the plurality of coil wires.

In the example illustrated in FIG. 2, the first coil wire 21a is formed by laminating a first coil conductor layer 121aa and a first coil conductor layer 121ab in the coil axial direction.

In the first coil wire 21a, in addition to the first coil conductor layer described above, at least one other coil conductor layer may be further laminated in the coil axial direction.

The first coil wire 21a may have a single-layer structure or may have a multi-layer structure.

The second coil wire 21b is present at the outermost position on the side surface 13b side of the element body 10 in the coil axial direction among the plurality of coil wires.

In the example illustrated in FIG. 2, the second coil wire 21b is formed by laminating a second coil conductor layer 121ba and a second coil conductor layer 121bb in the coil axial direction.

In the second coil wire 21b, in addition to the second coil conductor layer described above, at least one other coil conductor layer may be further laminated in the coil axial direction.

The second coil wire 21b may have a single-layer structure or may have a multi-layer structure.

At least one other coil wire may be present between the first coil wire 21a and the second coil wire 21b in the coil axial direction.

Examples of the conductive material constituting the coil wire include Ag, Au, Cu, Pd, Ni, Al, and alloys containing at least one of these metals.

The conductive materials constituting the plurality of coil wires may be the same as each other, may be different from each other, or may be partially different.

The dimensions of the plurality of coil wires in the coil axial direction may be the same as each other, may be different from each other, or may be partially different.

The dimensions of the plurality of coil wires in the direction orthogonal to the direction where the coil wires extend when viewed in the coil axial direction, that is, the widths when viewed in the coil axial direction may be the same as each other, may be different from each other, or may be partially different.

The coil wires adjacent to each other in the coil axial direction among the plurality of coil wires may be electrically connected with a connection conductor penetrating the insulating layer between the coil wires adjacent to each other in the coil axial direction interposed therebetween. That is, the coil 20 may be formed by electrically connecting the plurality of coil wires laminated in the coil axial direction with the connection conductors interposed therebetween.

In the example illustrated in FIG. 2, the first coil wire 21a and the second coil wire 21b are electrically connected with a connection conductor 29a penetrating the insulating layer 15d in the coil axial direction interposed therebetween.

In the example illustrated in FIG. 2, the connection conductor 29a includes a connection conductor layer 129aa.

In the connection conductor 29a, in addition to the connection conductor layer 129aa, at least one other connection conductor layer may be laminated in the coil axial direction.

The connection conductor 29a may have a single-layer structure or a multi-layer structure.

Examples of the conductive material constituting the connection conductor include Ag, Au, Cu, Pd, Ni, Al, and alloys containing at least one of these metals.

As described above, although at least one other coil wire may be present between the first coil wire 21a and the second coil wire 21b in the coil axial direction, that is, the coil 20 may include three or more coil wires obtained by adding at least one coil wire to the first coil wire 21a and the second coil wire 21b, by adjusting the position of the connection conductor, it is possible to form the coil 20 only with the first coil wire 21a and the second coil wire 21b.

When viewed in the coil axial direction, the coil 20 may have a shape including only a straight portion, a shape including only a curved portion, or a shape including a straight portion and a curved portion. For example, when viewed in the coil axial direction, the coil 20 may have, for example, a polygonal shape, a circular shape, or an elliptical shape.

As illustrated in FIG. 1, the first outer electrode 30a is electrically connected to one end portion of the coil 20. More specifically, as illustrated in FIG. 1, the first coil wire 21a constituting the coil 20 is electrically connected to the first outer electrode 30a with one first extended wire 22aa interposed therebetween.

In the example illustrated in FIG. 2, the first extended wire 22aa includes a first extended conductor layer 122aa.

In the first extended wire 22aa, in addition to the first extended conductor layer 122aa, at least one other extended conductor layer may be laminated in the coil axial direction.

The first extended wire 22aa may have a single-layer structure or may have a multi-layer structure.

As illustrated in FIG. 1, the second outer electrode 30b is electrically connected to the other end portion of the coil 20. More specifically, as illustrated in FIG. 1, the second coil wire 21b constituting the coil 20 may be electrically connected to the second outer electrode 30b with one second extended wire 22ba interposed therebetween.

In the example illustrated in FIG. 2, the second extended wire 22ba includes the second extended conductor layer 122ba.

In the second extended wire 22ba, in addition to the second extended conductor layer 122ba, at least one other extended conductor layer may be laminated in the coil axial direction.

The second extended wire 22ba may have a single-layer structure, or may have a multi-layer structure.

Examples of the conductive material constituting the extended wire include Ag, Au, Cu, Pd, Ni, Al, and alloys containing at least one of these metals.

The conductive materials constituting the first extended wire 22aa and the second extended wire 22ba may be the same as or different from each other.

As illustrated in FIG. 1, the first outer electrode 30a is exposed on the surface of the element body 10.

As illustrated in FIG. 1, the first outer electrode 30a is preferably exposed at least on the bottom surface 12b of the element body 10.

In the example illustrated in FIG. 1, the first outer electrode 30a extends from a part of the bottom surface 12b to a part of the end surface 11a of the element body 10. That is, in the example illustrated in FIG. 1, the first outer electrode 30a is exposed on a part of the end surface 11a of the element body 10, in addition to a part of the bottom surface 12b of the element body 10.

The first outer electrode 30a may be exposed only on the bottom surface 12b of the element body 10.

In the example illustrated in FIG. 2, the first outer electrode 30a is formed by laminating a first outer conductor layer 130aa, a first outer conductor layer 130ab, a first outer conductor layer 130ac, a first outer conductor layer 130ad, and a first outer conductor layer 130ae in the coil axial direction.

In the first outer electrode 30a, in addition to the first outer conductor layer described above, at least one other outer conductor layer may be further laminated in the coil axial direction.

The first outer electrode 30a may have a single-layer structure or a multi-layer structure.

As illustrated in FIG. 1, the second outer electrode 30b is exposed on the surface of the element body 10.

As illustrated in FIG. 1, the second outer electrode 30b is preferably exposed at least on the bottom surface 12b of the element body 10.

In the example illustrated in FIG. 1, the second outer electrode 30b extends from a part of the bottom surface 12b to a part of the end surface 11b of the element body 10. That is, in the example illustrated in FIG. 1, the second outer electrode 30b is exposed on a part of the end surface 11b of the element body 10, in addition to a part of the bottom surface 12b of the element body 10.

The second outer electrode 30b may be exposed only on the bottom surface 12b of the element body 10.

In the example illustrated in FIG. 2, the second outer electrode 30b is formed by laminating a second outer conductor layer 130ba, a second outer conductor layer 130bb, a second outer conductor layer 130bc, a second outer conductor layer 130bd, and a second outer conductor layer 130be in the coil axial direction.

In the second outer electrode 30b, in addition to the second outer conductor layer described above, at least one other outer conductor layer may be further laminated in the coil axial direction.

The second outer electrode 30b may have a single-layer structure or may have a multi-layer structure.

As described above, the first outer electrode 30a and the second outer electrode 30b are preferably exposed so as to be separated from each other at least at the bottom surface 12b of the element body 10. In the example illustrated in FIG. 1, the first outer electrode 30a and the second outer electrode 30b are provided so as to be separated from each other in a direction orthogonal to the coil axial direction (here, length direction L).

In addition, when each of the first outer electrode 30a and the second outer electrode 30b is exposed on the bottom surface 12b of the element body 10, which is a mounting surface, the mountability of the inductor component 1A is likely to be improved.

In the example illustrated in FIG. 1, the dimension of the first outer electrode 30a in the coil axial direction is smaller than the dimension of the element body 10 in the coil axial direction.

The dimension of the first outer electrode 30a in the coil axial direction may be the same as the dimension of the element body 10 in the coil axial direction.

In the example illustrated in FIG. 1, the dimension of the second outer electrode 30b in the coil axial direction is smaller than the dimension of the element body 10 in the coil axial direction.

The dimension of the second outer electrode 30b in the coil axial direction may be the same as the dimension of the element body 10 in the coil axial direction.

Examples of conductive materials constituting the outer electrode include Ag, Au, Cu, Pd, Ni, Al, and alloys containing at least one of these metals.

The first outer electrode 30a may have, in order from the coil 20 side, a base electrode containing the above-described conductive material (for example, Ag), a Ni-plated electrode, and an Sn-plated electrode. In this case, in the first outer electrode 30a, the base electrode may form an integral surface with the surface of the element body 10 (in FIG. 1, the end surface 11a and the bottom surface 12b of the element body 10), and the Ni-plated electrode and the Sn-plated electrode may protrude from the surface of the element body 10 (in FIG. 1, the end surface 11a and the bottom surface 12b of the element body 10) so as to cover the base electrode.

The second outer electrode 30b may have, in order from the coil 20 side, a base electrode containing the above-described conductive material (for example, Ag), a Ni-plated electrode, and an Sn-plated electrode. In this case, in the second outer electrode 30b, the base electrode may form an integral surface with the surface of the element body 10 (in FIG. 1, the end surface 11b and the bottom surface 12b of the element body 10), and the Ni-plated electrode and the Sn-plated electrode may protrude from the surface of the element body 10 (in FIG. 1, the end surface 11b and the bottom surface 12b of the element body 10) so as to cover the base electrode.

The conductive materials constituting the first outer electrode 30a and the second outer electrode 30b may be the same as or different from each other.

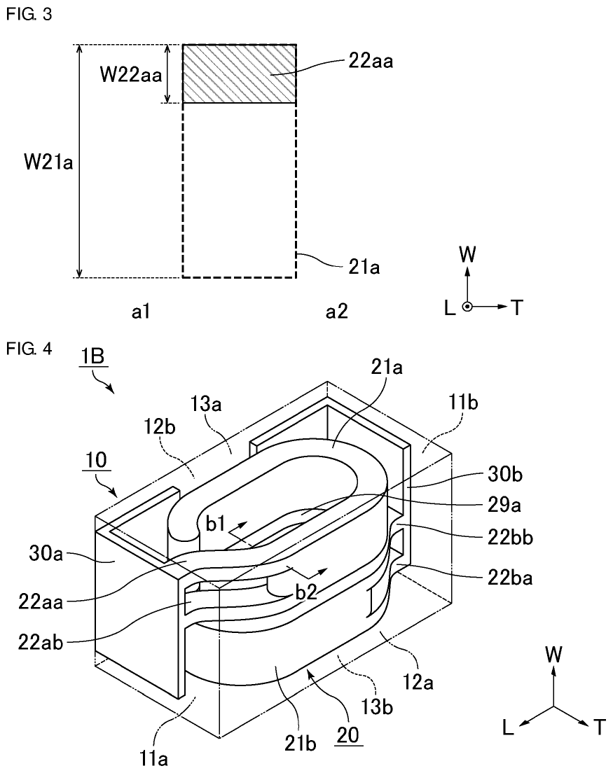

FIG. 3 is a schematic sectional view illustrating an example of a cross section along the line segment a1-a2 of the inductor component illustrated in FIG. 1. More specifically, FIG. 3 illustrates a cross section of the inductor component 1A including the boundary between the first coil wire 21a and the first extended wire 22aa.

As illustrated in FIG. 3, the dimension W22aa of the first extended wire 22aa in the coil axial direction is smaller than the dimension W21a of the first coil wire 21a in the coil axial direction.

In the inductor component 1A, since the dimension W22aa of the first extended wire 22aa in the coil axial direction is smaller than the dimension W21a of the first coil wire 21a in the coil axial direction, residual stress in the vicinity of the first extended wire 22aa during firing in the manufacturing process is suppressed. Therefore, in the inductor component 1A, interfacial delamination between the first extended wire 22aa and the element body 10 due to the stress remaining in the vicinity of the first extended wire 22aa is suppressed, and as a result, the occurrence of cracks is suppressed.

On the other hand, during the manufacturing process, the inductor component, particularly the surface of the element body, is subjected to an impact load due to the collision of an abrasive material, for example, during a polishing treatment for rounding the corner portions and ridge portions of the element body (for example, barrel polishing treatment), or is subjected to a chemical erosion load due to penetration of the plating solution during a plating treatment for forming the outer electrode. Therefore, in the inductor component, during the manufacturing process, such an external load such as an impact load and a chemical erosion load acts as a trigger and is combined with the stress remaining in the vicinity of the extended wire during firing, interfacial delamination between the extended wire and the element body is likely to occur, and as a result, cracks may easily occur. On the other hand, in the inductor component 1A, since the dimension W22aa of the first extended wire 22aa in the coil axial direction is smaller than the dimension W21a of the first coil wire 21a in the coil axial direction, the stress remaining in the vicinity of the first extended wire 22aa is suppressed during firing in the manufacturing process. Therefore, even when an external load such as the above-described impact load and the chemical erosion load is applied to the inductor component 1A, interfacial delamination between the first extended wire 22aa and the element body 10 triggered by the external load is unlikely to occur, and as a result, cracks are unlikely to occur.

As described above, according to the inductor component 1A, it is possible to realize an inductor component capable of suppressing the occurrence of cracks caused by the stress remaining in the vicinity of the first extended wire 22aa during the manufacturing process.

According to the inductor component 1A, since the stress remaining in the vicinity of the first extended wire 22aa during firing in the manufacturing process can be suppressed, even when it is attempted to improve the coil characteristics by increasing at least one of the aspect ratio and the cross-sectional area of the coil wire (for example, the first coil wire 21a), the occurrence of cracks can be suppressed.

At least a part of the first extended wire 22aa may have a portion in which the dimension in the coil axial direction is smaller than that of the first coil wire 21a. That is, even when the first extended wire 22aa may have the portion in which the dimension in the coil axial direction is smaller than that of the first coil wire 21a over a part of the first extended wire 22aa in the direction where the first extended wire 22aa extends, or over the entire first extended wire 22aa.

The dimension of the coil wire in the coil axial direction is defined as the maximum dimension in the coil axial direction of a cross section perpendicular to the direction where the coil wire extends. Even in a case where the outer shape of the coil wire is uneven when the cross section of the coil wire is viewed, the dimension of the coil wire in the coil axial direction is defined as the maximum dimension in the coil axial direction including the unevenness.

The dimension of the extended wire in the coil axial direction is defined as the maximum dimension in the coil axial direction of a cross section perpendicular to the direction where the extended wire extends. Even in a case where the outer shape of the extended wire is uneven when the cross section of the extended wire is viewed, the dimension of the extended wire in the coil axial direction is defined as the maximum dimension in the coil axial direction including the unevenness. In a case where the dimension of the extended wire in the coil axial direction partially differs along the direction where the extended wire extends (for example, refer to Embodiment 3 to be described later), the cross section of the extended wire is defined for each portion of the extended wire having a different dimension in the coil axial direction.

As illustrated in FIG. 1, the first coil wire 21a and the first extended wire 22aa are preferably connected at a corner portion D corresponding to a portion where the first extended wire 22aa begins to extend obliquely from a linear portion of the first coil wire 21a, when viewed in the coil axial direction.

In the inductor component 1A, since the first coil wire 21a and the first extended wire 22aa are connected at the corner portions, the first coil wire 21a is connected to the first extended wire 22aa having a smaller dimension in the coil axial direction than that of the first coil wire 21a at the corner portion where the stress is likely to remain during firing in the manufacturing process. Therefore, the stress remaining in the corner portion is suppressed. Therefore, in the inductor component 1A, even when an external load is applied to the top surface 12a of the element body 10, the interfacial delamination between the first extended wire 22aa and the element body 10 triggered by the external load is suppressed, and as a result, the occurrence of cracks is suppressed.

In this specification, when viewed in the coil axial direction, in the path where the coil wire is connected to the outer electrode, the wire extending toward the outer electrode, while being inclined with respect to the linear portion of the coil wire is defined as the extended wire (for example, an example illustrated in FIG. 1). In this case, when viewed in the coil axial direction, the coil wire and the extended wire are not present on the same straight line with a connecting portion between both wires as a boundary. In a case where a wire corresponding to the extended wire defined as described above is not found when viewed in the coil axial direction, a wire not overlapping a winding portion of the coil when viewed in the coil axial direction (protrudes from the winding portion of the coil) is defined as an extended wire (for example, an example different from that illustrated in FIG. 1).

As illustrated in FIG. 1, in the inductor component 1A, the second coil wire 21b may be electrically connected to the second outer electrode 30b with one second extended wire 22ba interposed therebetween. In this case, as illustrated in FIG. 1, the dimension of the second extended wire 22ba in the coil axial direction is preferably smaller than the dimension of the second coil wire 21b in the coil axial direction.

Other aspects of the second extended wire 22ba are preferably the same as those of the first extended wire 22aa described above.

The inductor component 1A is manufactured, for example, by the following method.

### Step of Producing Mother Multilayer Body

First, for example, an insulating paste containing glass materials containing borosilicate glass as a main component is repeatedly applied by screen printing or the like to form an insulating paste layer, which later becomes the insulating layer 15a.

Next, for example, a photosensitive conductive paste containing Ag or the like as a main metal component is applied by screen printing or the like to form a photosensitive conductive paste layer on the insulating paste layer. Furthermore, after irradiating the photosensitive conductive paste layer with ultraviolet rays or the like by using a photomask, the layer is developed with an alkaline solution or the like, so that a coil conductor layer, which later becomes the second coil conductor layer 121ba, an outer conductor layer, which later becomes the first outer conductor layer 130aa and the second outer conductor layer 130ba, and an extended conductor layer, which is connected to the coil conductor layer and the outer conductor layer and later becomes the second extended conductor layer 122ba, are formed at a plurality of portions on the insulating paste layer.

When forming the coil conductor layer, the extended conductor layer, and the outer conductor layer, instead of exposure using a photomask, for example, DI exposure (also called direct image exposure or direct writing) without using a photomask may be performed.

Next, for example, a photosensitive insulating paste is applied by screen printing or the like, so that an insulating paste layer, which later becomes the insulating layers 15b and 15c, is formed on the insulating paste layer, which later becomes the insulating layer 15a. Furthermore, after irradiating the insulating paste layer, which later becomes the insulating layer 15c, with ultraviolet rays or the like by using a photomask, the layer is developed with an alkaline solution or the like, so that a via hole and an opening are formed in the insulating paste layer, which later becomes the insulating layer 15c. The via hole formed here partially overlaps the coil conductor layer, which later becomes the second coil conductor layer 121ba, does not overlap the extended conductor layer, which later becomes the second extended conductor layer 122ba, and has the same shape as the coil conductor layer, which later becomes the second coil conductor layer 121bb. The openings formed here overlap the outer conductor layer, which later becomes the first outer conductor layer 130aa and the second outer conductor layer 130ba.

When forming the insulating paste layer provided with the via hole and the opening, instead of exposure using a photomask, for example, DI exposure without using a photomask may be performed.

Next, for example, a photosensitive conductive paste containing Ag or the like as a main metal component is applied by screen printing or the like to form a new photosensitive conductive paste layer on the insulating paste layer to be the insulating layer 15c later, while being formed inside the via hole and opening. Furthermore, after irradiating the photosensitive conductive paste layer with ultraviolet rays or the like by using a photomask, the layer is developed with an alkaline solution or the like, so that a connection conductor layer, which is connected to the coil conductor layer and later becomes the connection conductor layer 129aa, is formed, while a coil conductor layer, which later becomes the second coil conductor layer 121bb, is formed inside the via hole. Furthermore, while an outer conductor layer, which later becomes the first outer conductor layer 130ab, connected to an outer conductor layer, which later becomes the first outer conductor layer 130aa, is formed inside the opening, an outer conductor layer, which later becomes the first outer conductor layer 130ac, is formed on the outer conductor layer. Furthermore, while an outer conductor layer, which later becomes the second outer conductor layer 130bb, connected to an outer conductor layer, which later becomes the second outer conductor layer 130ba, is formed inside the opening, an outer conductor layer, which later becomes the second outer conductor layer 130bc, is formed on the outer conductor layer.

When forming the coil conductor layer, the connection conductor layer, and the outer conductor layer, instead of exposure using a photomask, for example, DI exposure without using a photomask may be performed.

Next, for example, a photosensitive insulating paste is applied by screen printing or the like, so that an insulating paste layer, which later becomes the insulating layers 15d and 15e, is formed on the insulating paste layer, which later becomes the insulating layer 15c. Furthermore, after irradiating the insulating paste layer, which later becomes the insulating layer 15e, with ultraviolet rays or the like by using a photomask, the layer is developed with an alkaline solution or the like, so that a via hole and an opening are formed in the insulating paste layer, which later becomes the insulating layer 15e. The via hole formed here overlaps the connection conductor layer, which later becomes the connection conductor layer 129aa, and has the same shape as the coil conductor layer, which later becomes the first coil conductor layer 121aa. The openings formed here overlap the outer conductor layers, which later become the first outer conductor layer 130ac and the second outer conductor layer 130bc.

Next, for example, a photosensitive conductive paste containing Ag or the like as a main metal component is applied by screen printing or the like to form a new photosensitive conductive paste layer on the insulating paste layer to be the insulating layer 15e later, while being formed inside the via hole and opening. Furthermore, after irradiating the photosensitive conductive paste layer with an ultraviolet rays or the like by using a photomask, the layer is developed with an alkaline solution or the like, so that a coil conductor layer, which is connected to the coil conductor layer and later becomes the first coil conductor layer 121ab, is formed, while a coil conductor layer, which later becomes the first coil conductor layer 121aa, is formed inside the via hole. Furthermore, while an outer conductor layer, which later becomes the first outer conductor layer 130ad, connected to an outer conductor layer, which later becomes the first outer conductor layer 130ac, is formed inside the opening, an outer conductor layer, which later becomes the first outer conductor layer 130ae, is formed on the outer conductor layer. Furthermore, while an outer conductor layer, which later becomes the second outer conductor layer 130bd, connected to an outer conductor layer, which later becomes the second outer conductor layer 130bc, is formed inside the opening, an outer conductor layer, which later becomes the second outer conductor layer 130be, is formed on the outer conductor layer. Furthermore, an extended conductor layer, which later becomes the first extended conductor layer 122aa, connected to the coil conductor layer, which later becomes the first coil conductor layer 121ab, and the outer conductor layer, which later becomes the first outer conductor layer 130ae, is formed on the insulating paste layer, which later becomes the insulating layer 15e.

Finally, for example, an insulating paste containing glass materials containing borosilicate glass as a main component is repeatedly applied by screen printing or the like to form an insulating paste layer to be the insulating layers 15f and 15g later.

As described above, a mother multilayer body is produced.

A method of forming conductor patterns of the coil conductor layer, the extended conductor layer, the connection conductor layer, and the outer conductor layer is not limited to the photolithography method described above, and may be, for example, a method of printing and laminating a conductive paste using a screen printing plate having openings in the shape of the conductor pattern, a method of forming a conductor film by a sputtering method, a vapor deposition method, a method of pressure-bonding a foil, or the like, and then etching the conductor film so as to have the shape of a conductor pattern, or a method of forming a negative pattern by a semi-additive method, forming a plating film, and then removing unnecessary portions of the plating film by etching or the like so as to form the shape of a conductor pattern.

When forming the conductor patterns of the coil conductor layer, the extended conductor layer, the connection conductor layer, and the outer conductor layer, a high aspect ratio is achieved by forming the conductor pattern in multiple stages, so that loss due to resistance at high frequencies can be reduced. The method of forming the conductor patterns in multiple stages is not particularly limited, and may be, for example, a method of repeatedly superimposing the conductor pattern by repeating the step using the photolithography method as described above, a method of repeatedly superimposing conductor patterns formed by a semi-additive method, a method of superimposing conductor patterns formed by a semi-additive method and conductor patterns formed by etching a plating film grown separately by plating in random order, or a method of further plating and growing a plating film formed by a semi-additive method.

The conductive material constituting the conductor patterns of the coil conductor layer, the extended conductor layer, the connection conductor layer, and the outer conductor layer is not limited to the above-described photosensitive conductive paste containing Ag or the like as a main metal component, and may be, for example, a conductor containing a metal such as Ag, Au, and Cu formed by a sputtering method, a vapor deposition method, a method of pressure-bonding a foil, a plating method, or the like.

A method of forming the insulating paste layer is not limited to the photolithography method described above, and may be, for example, a method of pressure-bonding a sheet made of an insulating material, or a method of spin-coating an insulating material, or a method of spray-coating an insulating material.

The method of forming the insulating paste layer provided with the via hole and the opening is not limited to the photolithography method described above, and may be, for example, a method in which an insulating film is formed by a method such as pressure-bonding a sheet made of an insulating material, spin-coating an insulating material, or spray-coating an insulating material, and then the via hole and the opening are provided by subjecting the insulating film to laser processing, drill processing, or the like.

The insulating material that constitutes the insulating paste layer is not limited to the above-described glass materials containing borosilicate glass as a main component, and may be, for example, ceramic materials, organic materials such as epoxy resins, fluororesins, and polymer resins, composite materials such as glass epoxy resins, or the like. As an insulating material, a material having a small dielectric constant and a small dielectric loss is particularly preferable.

### Step of Forming Element Body, Coil, and Outer Electrode

First, the mother multilayer body is cut with a dicing machine or the like to separate into a plurality of unfired multilayer bodies.

The unfired multilayer body includes an insulating paste multilayer portion in which the insulating paste layers are laminated, a coil conductor multilayer portion in which the coil conductor layers are laminated such that adjacent coil conductor layers are electrically connected to each other with a connection conductor layer interposed therebetween, and an outer conductor multilayer portion in which the outer conductor layers are laminated.

When being separated into the unfired multilayer body, for example, the outer conductor multilayer portions are exposed in two portions on at least the bottom surface of the insulating paste multilayer portion included in the cut surface of the unfired multilayer body.

Next, a multilayer body is produced by firing the unfired multilayer body.

When the unfired multilayer body is fired, the insulating paste layer becomes the insulating layer, and the insulating paste multilayer portion becomes the element body 10. In addition, when the unfired multilayer body is fired, the coil conductor layer becomes the coil wire, so that the coil conductor multilayer portion becomes the coil 20. Furthermore, when the unfired multilayer body is fired, one of the two outer conductor multilayer portions becomes a part of the first outer electrode 30a and the other becomes a part of the second outer electrode 30b.

Next, the corner portions and ridge portions of the element body 10 may be rounded by barrel polishing the obtained multilayer body, for example.

Finally, using the two outer conductor multilayer portions after firing as base electrodes, a Ni-plated electrode and an Sn-plated electrode are sequentially formed on the surfaces of each of the base electrodes by plating treatment. Each of the thicknesses of the Ni-plated electrode and the Sn-plated electrode is, for example, 2 μm or more and 10 μm or less (i.e., from 2 μm to 10 μm).

In this manner, the first outer electrode 30a and the second outer electrode 30b, which have the base electrode, the Ni-plated electrode, and the Sn-plated electrode in order from the surface side of the element body 10, are formed. In this case, in the first outer electrode 30a, the base electrode may form an integral surface with the surface of the element body 10 (in FIG. 1, the end surface 11a and the bottom surface 12b of the element body 10), and the Ni-plated electrode and the Sn-plated electrode may protrude from the surface of the element body 10 (in FIG. 1, the end surface 11a and the bottom surface 12b of the element body 10) so as to cover the base electrode. In addition, in the second outer electrode 30b, the base electrode may form an integral surface with the surface of the element body 10 (in FIG. 1, the end surface 11b and the bottom surface 12b of the element body 10), and the Ni-plated electrode and the Sn-plated electrode may protrude from the surface of the element body 10 (in FIG. 1, the end surface 11b and the bottom surface 12b of the element body 10) so as to cover the base electrode.

A method of forming the outer electrodes is not limited to a method of plating the outer conductor multilayer portion exposed on the cut surface of the unfired multilayer body (for example, at least the bottom surface of the insulating paste multilayer portion) as described above, and may be, for example, a method of exposing the outer conductor multilayer portion on the cut surface of the unfired multilayer body (for example, at least the bottom surface of the insulating paste multilayer portion) as described above, then immersing (dipping) the exposed portion of the outer conductor multilayer portion in a conductive paste or forming a film of the conductive paste on the exposed portion of the outer conductor multilayer portion by a sputtering method, and then plating the exposed portion.

As described above, the inductor component 1A is manufactured.

The inductor component 1A is manufactured with a size of 0402 (0.4 mm×0.2 mm×0.2 mm), for example. The size of inductor component 1A is not limited to 0402 (0.4 mm×0.2 mm×0.2 mm) size.

### Embodiment 2

In an inductor component according to Embodiment 2 of the present disclosure, the first coil wire is electrically connected to the first outer electrode with a plurality of first extended wires arranged in the coil axial direction interposed therebetween. The inductor component according to Embodiment 2 of the present disclosure is the same as the inductor component according to Embodiment 1 of the present disclosure except for this point.

FIG. 4 is a schematic perspective view illustrating an example of an inductor component according to Embodiment 2 of the present disclosure.

In an inductor component 1B illustrated in FIG. 4, the first coil wire 21a is electrically connected to the first outer electrode 30a with two first extended wires 22aa and 22ab arranged in the coil axial direction interposed therebetween.

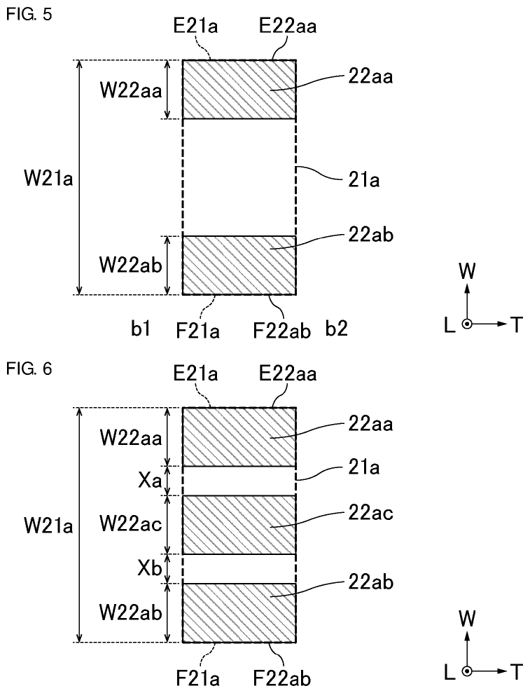

FIG. 5 is a schematic sectional view illustrating an example of a cross section along the line segment b1-b2 of the inductor component illustrated in FIG. 4. More specifically, FIG. 5 illustrates a cross section of the inductor component 1B including the boundary between the first coil wire 21a and the first extended wire 22aa and the boundary between the first coil wire 21a and the first extended wire 22ab.

As illustrated in FIG. 5, each of the dimension W22aa of the first extended wire 22aa in the coil axial direction and the dimension W22ab of the first extended wire 22ab in the coil axial direction is smaller than the dimension W21a of the first coil wire 21a in the coil axial direction.

FIGS. 4 and 5 illustrate an example of a configuration in which two first extended wires are arranged in the coil axial direction, but three or more first extended wires may be arranged in the coil axial direction. Hereinafter, an example of a configuration in which three or four first extended wires are arranged in the coil axial direction will be described.

FIG. 6 is a schematic sectional view illustrating an example of a configuration in which three first extended wires are arranged in a coil axial direction with respect to a configuration illustrated in FIG. 5.

As illustrated in FIG. 6, a first extended wire 22ac located between the first extended wire 22aa and the first extended wire 22ab in the coil axial direction is provided as the three first extended wires, in addition to the first extended wire 22aa and the first extended wire 22ab.

As illustrated in FIG. 6, each of the dimension W22aa of the first extended wire 22aa in the coil axial direction, the dimension W22ab of the first extended wire 22ab in the coil axial direction, and the dimension W22ac of the first extended wire 22ac in the coil axial direction is smaller than the dimension W21a of the first coil wire 21a in the coil axial direction.

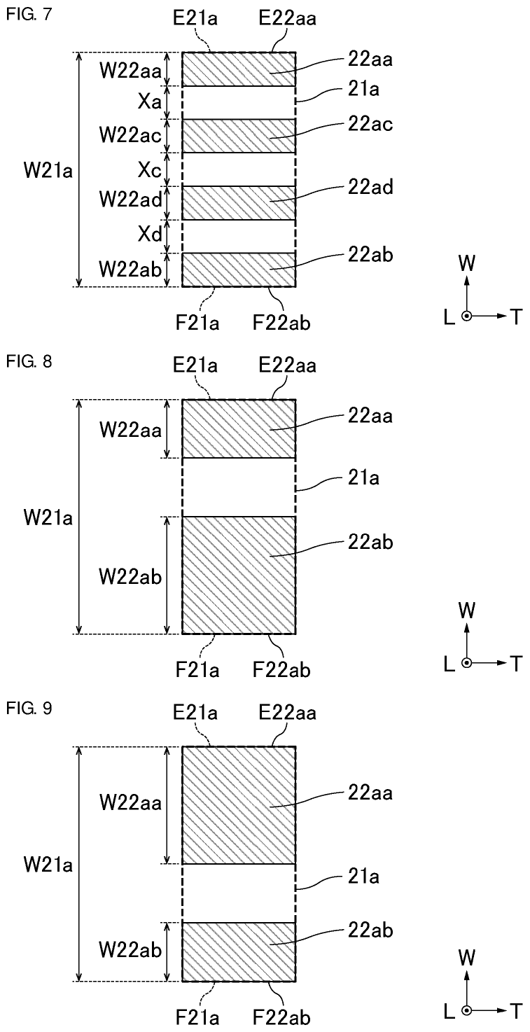

FIG. 7 is a schematic sectional view illustrating an example of a configuration in which four first extended wires are arranged in the coil axial direction with respect to the configuration illustrated in FIG. 6.

As illustrated in FIG. 7, a first extended wire 22ad located between the first extended wire 22ab and the first extended wire 22ac in the coil axial direction is provided as the four first extended wires, in addition to the first extended wire 22aa, the first extended wire 22ab, and the first extended wire 22ac.

As illustrated in FIG. 7, each of the dimension W22aa of the first extended wire 22aa in the coil axial direction, the dimension W22ab of the first extended wire 22ab in the coil axial direction, the dimension W22ac of the first extended wire 22ac in the coil axial direction, and the dimension W22ad of the first extended wire 22ad in the coil axial direction is smaller than the dimension W21a of the first coil wire 21a in the coil axial direction.

As described above, in an inductor component (for example, inductor component 1B) in which the first coil wire 21a is electrically connected to the first outer electrode 30a with the plurality of first extended wires arranged in the coil axial direction interposed therebetween, an increase in DC resistance (Rdc) is suppressed compared to an inductor component (for example, inductor component 1A) in which the first coil wire 21a is electrically connected to the first outer electrode 30a with one first extended wire interposed therebetween.

As illustrated in FIGS. 5, 6, and 7, it is preferable that the dimensions of the plurality of first extended wires in the coil axial direction are the same as each other.

In the example illustrated in FIG. 5, the dimension W22aa of the first extended wire 22aa in the coil axial direction and the dimension W22ab of the first extended wire 22ab in the coil axial direction are the same as each other.

In the example illustrated in FIG. 6, the dimension W22aa of the first extended wire 22aa in the coil axial direction, the dimension W22ab of the first extended wire 22ab in the coil axial direction, and the dimension W22ac of the first extended wire 22ac in the coil axial direction are the same as each other.

In the example illustrated in FIG. 7, the dimension W22aa of the first extended wire 22aa in the coil axial direction, the dimension W22ab of the first extended wire 22ab in the coil axial direction, the dimension W22ac of the first extended wire 22ac in the coil axial direction, and the dimension W22ad of the first extended wire 22ad in the coil axial direction are the same as each other.

As described above, in the inductor component in which the dimensions of the plurality of first extended wires in the coil axial direction are the same as each other, an increase in DC resistance is suppressed compared to an inductor component in which the dimensions of the plurality of first extended wires in the coil axial direction are different from each other or partially different. Furthermore, in an inductor component in which the dimensions of the plurality of first extended wires in the coil axial direction are the same as each other, the formation of the plurality of first extended wires is facilitated, and the pattern design of the coil 20 is facilitated.

The dimensions of the plurality of first extended wires in the coil axial direction may be different from each other, or may be partially different.

FIG. 8 is a schematic sectional view illustrating a modification example of the configuration illustrated in FIG. 5. FIG. 9 is a schematic sectional view illustrating another modification example of the configuration illustrated in FIG. 5.

As illustrated in FIGS. 8 and 9, the first extended wire 22aa is located on the surface side of the element body 10 (refer to FIG. 4) from the first extended wire 22ab in the coil axial direction. Hereinafter, the first extended wire 22aa is taken as an example of the first outer side portion extended wire in the inductor component of the present disclosure.

As illustrated in FIGS. 8 and 9, the first extended wire 22ab is located inside the element body 10 (refer to FIG. 4) from the first extended wire 22aa in the coil axial direction.

In this specification, the fact that one wire is located further inside the element body than the other wire means that the distance between one wire and the surface of the element body in the coil axial direction is larger than the distance between the other wire and the surface of the element body in the coil axial direction with respect to the same surface of the element body. More specifically, the fact that one wire is located further inside the element body than the other wire means that the minimum distance between the one wire and the surface of the element body is larger than the minimum distance between the other wire and the surface of the element body in the coil axial direction.

That is, as illustrated in FIGS. 8 and 9, in the first extended wire 22ab, the distance from the surface (side surface 13a in FIG. 4) of the element body 10 (refer to FIG. 4) is larger than that of the first extended wire 22aa in the coil axial direction. Hereinafter, the first extended wire 22ab is taken as an example of the first inner side portion extended wire in the inductor component of the present disclosure.

As illustrated in FIGS. 8 and 9, the dimension W22aa of the first extended wire 22aa in the coil axial direction and the dimension W22ab of the first extended wire 22ab in the coil axial direction may be different from each other.

In the example illustrated in FIG. 8, the dimension W22aa of the first extended wire 22aa in the coil axial direction is smaller than the dimension W22ab of the first extended wire 22ab in the coil axial direction.

In the example illustrated in FIG. 9, the dimension W22ab of the first extended wire 22ab in the coil axial direction is smaller than the dimension W22aa of the first extended wire 22aa in the coil axial direction.

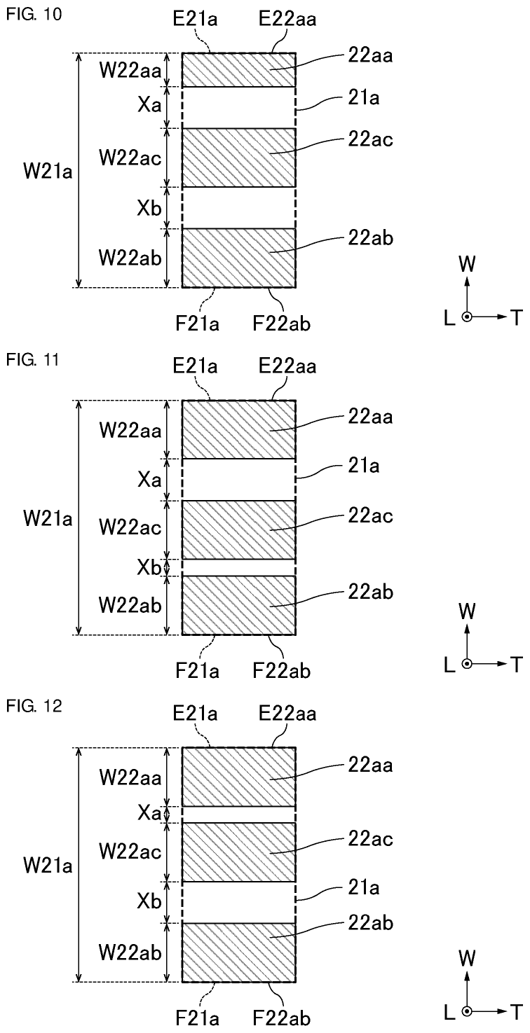

FIG. 10 is a schematic sectional view illustrating a modification example of the configuration illustrated in FIG. 6.

As illustrated in FIG. 10, the first extended wire 22ac is located between the first extended wire 22aa and the first extended wire 22ab in the coil axial direction so as to be adjacent to both wires. Hereinafter, the first extended wire 22ac is taken as an example of a first intermediate portion extended wire in the inductor component of the present disclosure.

As illustrated in FIG. 10, the dimension W22aa of the first extended wire 22aa in the coil axial direction, the dimension W22ab of the first extended wire 22ab in the coil axial direction, and the dimension W22ac of the first extended wire 22ac in the coil axial direction may be partially different.

In the example illustrated in FIG. 10, the dimension W22ab of the first extended wire 22ab in the coil axial direction and the dimension W22ac of the first extended wire 22ac in the coil axial direction are the same as each other. On the other hand, the dimension W22aa of the first extended wire 22aa in the coil axial direction is smaller than the dimension W22ab of the first extended wire 22ab in the coil axial direction and the dimension W22ac of the first extended wire 22ac in the coil axial direction.

As described above, in the inductor component in which the dimensions of the plurality of first extended wires in the coil axial direction are different from each other or partially different, among the stress remaining in the vicinity of the first extended wire during firing in the manufacturing process, the stress in the path to which the external load (particularly, chemical erosion load) is applied is easily suppressed.

In this case, when the dimension W22aa of the first extended wire 22aa in the coil axial direction is smaller than the dimension W22ab of the first extended wire 22ab in the coil axial direction, since the dimension W22aa in the coil axial direction of the first extended wire 22aa close to the surface of the element body 10 (here, the side surface 13a), which is likely to be subjected to an external load (particularly, chemical erosion load), is reduced, the stress remaining in the vicinity of the first extended wire 22aa during firing in the manufacturing process is suppressed, and in particular, the stress in the path to which the external load (particularly, chemical erosion load) is applied in the vicinity of the first extended wire 22aa is easily suppressed.

In addition, when the dimension W22ab of the first extended wire 22ab in the coil axial direction is smaller than the dimension W22aa of the first extended wire 22aa in the coil axial direction, good coil characteristics are easily ensured.

As illustrated in FIGS. 6 and 7, in a case where the plurality of first extended wires include three or more first extended wires, the intervals between the plurality of first extended wires in the coil axial direction are preferably the same as each other.

In the example illustrated in FIG. 6, the interval Xa in the coil axial direction between the first extended wire 22aa and the first extended wire 22ac and the interval Xb in the coil axial direction between the first extended wire 22ab and the first extended wire 22ac are the same as each other.

In the example illustrated in FIG. 7, the interval Xa in the coil axial direction between the first extended wire 22aa and the first extended wire 22ac, the interval Xc in the coil axial direction between the first extended wire 22ac and the first extended wire 22ad, and the interval Xd in the coil axial direction between the first extended wire 22ab and the first extended wire 22ad are the same as each other.

As described above, in the inductor component in which the intervals between the plurality of first extended wires in the coil axial direction are the same as each other, among the stress remaining in the vicinity of the first extended wire during firing in the manufacturing process, the stress in the path to which the external load (particularly, chemical erosion load) is applied is suppressed compared to the inductor component in which the intervals between the plurality of first extended wires in the coil axial direction are different from each other or partially different. Furthermore, in the inductor component in which the intervals between the plurality of first extended wires in the coil axial direction are the same as each other, the formation of the plurality of first extended wires is facilitated, and the degree of freedom in designing the pattern of the coil 20 is increased.

The intervals between the plurality of first extended wires in the coil axial direction may be different from each other, or may be partially different.

FIG. 11 is a schematic sectional view illustrating another modification example of the configuration illustrated in FIG. 6. FIG. 12 is a schematic sectional view illustrating still another modification example of the configuration illustrated in FIG. 6.

As illustrated in FIGS. 11 and 12, the interval Xa in the coil axial direction between the first extended wire 22aa and the first extended wire 22ac and the interval Xb in the coil axial direction between the first extended wire 22ab and the first extended wire 22ac may be different from each other.

In the example illustrated in FIG. 11, the interval Xa in the coil axial direction between the first extended wire 22aa and the first extended wire 22ac is larger than the interval Xb in the coil axial direction between the first extended wire 22ab and the first extended wire 22ac.

In the example illustrated in FIG. 12, the interval Xb in the coil axial direction between the first extended wire 22ab and the first extended wire 22ac is larger than the interval Xa in the coil axial direction between the first extended wire 22aa and the first extended wire 22ac.

As described above, in the inductor component in which the intervals between the plurality of first extended wires in the coil axial direction are different from each other or partially different, among the stress remaining in the vicinity of the first extended wire during firing in the manufacturing process, the stress in the path to which the external load (particularly, chemical erosion load) is applied is easily suppressed.

In this case, when the interval Xa between the first extended wire 22aa and the first extended wire 22ac in the coil axial direction is larger than the interval Xb in the coil axial direction between the first extended wire 22ab and the first extended wire 22ac, since it is possible to suppress the concentration of extended wires in a region close to the surface of the element body 10 (here, the side surface 13a), stress remaining in the vicinity of the extended wire (particularly, first extended wire 22aa) is suppressed in a region close to the surface of the element body 10 (here, the side surface 13a) during firing in the manufacturing process.

In addition, when the interval Xb in the coil axial direction between the first extended wire 22ab and the first extended wire 22ac is larger than the interval Xa in the coil axial direction between the first extended wire 22aa and the first extended wire 22ac, good coil characteristics are easily ensured.

The interval between the two extended wires in the coil axial direction is defined as the distance in the coil axial direction between the outermost end on the other extended wire side in the cross section of one extended wire in which the dimension in the coil axial direction is defined as described above, and the outermost end of the one extended wire side in the cross section of the other extended wire in which the dimension in the coil axial direction is defined as described above.

As illustrated in FIGS. 5, 6, 7, 8, 9, 10, 11, and 12, when viewed in the length direction L orthogonal to the coil axial direction, one end portion (here, the end portion on the side surface 13a side of the element body 10) E21a of the first coil wire 21a, and an end portion (here, the end portion on the side surface 13a side of the element body 10) E22aa of the first extended wire 22aa opposite to the first extended wire 22ab are preferably located at the same height in the coil axial direction. Furthermore, as illustrated in FIGS. 5, 6, 7, 8, 9, 10, 11, and 12, when viewed in the length direction L, the other end portion (here, the end portion on the side surface 13b side of the element body 10) F21a of the first coil wire 21a located further inside the element body 10 than one end portion (here, the end portion on the side surface 13a side of the element body 10) E21a of the first coil wire 21a, that is, the other end portion (here, the end portion on the side surface 13b side of the element body 10) F21a of the first coil wire 21a having a larger distance from the surface of the element body 10 (here, the side surface 13a) than one end portion (here, the end portion on the side surface 13a side of the element body 10) E21a of the first coil wire 21a, and the end portion (here, the end portion on the side surface 13b side of the element body 10) F22ab of the first extended wire 22ab opposite to the first extended wire 22aa are preferably located at the same height in the coil axial direction.

As described above, in an inductor component in which the first extended wire 22aa and the first extended wire 22ab are separated as much as possible in the coil axial direction, since the portions where the stress remains are dispersed during firing in the manufacturing process, local increases in stress are suppressed.

As illustrated in FIG. 4, in the inductor component 1B, the second coil wire 21b may be electrically connected to the second outer electrode 30b with two second extended wires 22ba and 22bb arranged in the coil axial direction interposed therebetween. Similarly, the second coil wire 21b may be electrically connected to the second outer electrode 30b with three or more second extended wires arranged in the coil axial direction interposed therebetween. That is, the second coil wire 21b may be electrically connected to the second outer electrode 30b with a plurality of second extended wires arranged in the coil axial direction interposed therebetween.

An aspect of the plurality of second extended wires is preferably the same as the aspect of the plurality of first extended wires described above.

### Embodiment 3

In an inductor component according to Embodiment 3 of the present disclosure, the dimension of the first extended wire in the coil axial direction increases from the first outer electrode side toward the first coil wire side. The inductor component according to Embodiment 3 of the present disclosure is the same as the inductor component according to Embodiment 1 of the present disclosure except for this point.

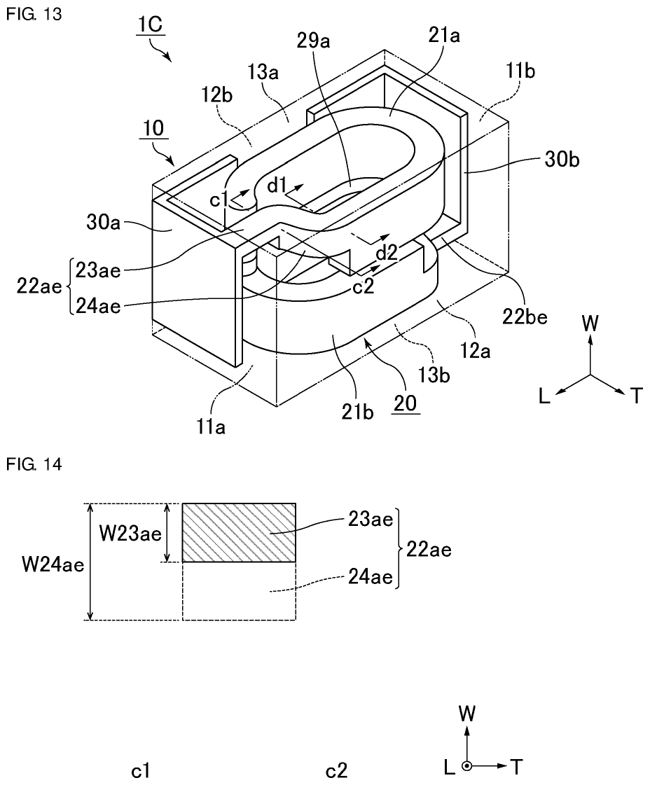

FIG. 13 is a schematic perspective view illustrating an example of an inductor component according to Embodiment 3 of the present disclosure.

In an inductor component 1C illustrated in FIG. 13, the first coil wire 21a is electrically connected to the first outer electrode 30a with the first extended wire 22ae interposed therebetween.

The first extended wire 22ae includes an extended wire portion 23ae and an extended wire portion 24ae.

The extended wire portion 23ae is connected to the first outer electrode 30a.

The extended wire portion 24ae is provided between the extended wire portion 23ae and the first coil wire 21a, and is connected to both components.

FIG. 14 is a schematic sectional view illustrating an example of a cross section along the line segment c1-c2 of the inductor component illustrated in FIG. 13. More specifically, FIG. 14 illustrates a cross section of the inductor component 1C including the boundary between the extended wire portion 23ae and the extended wire portion 24ae.

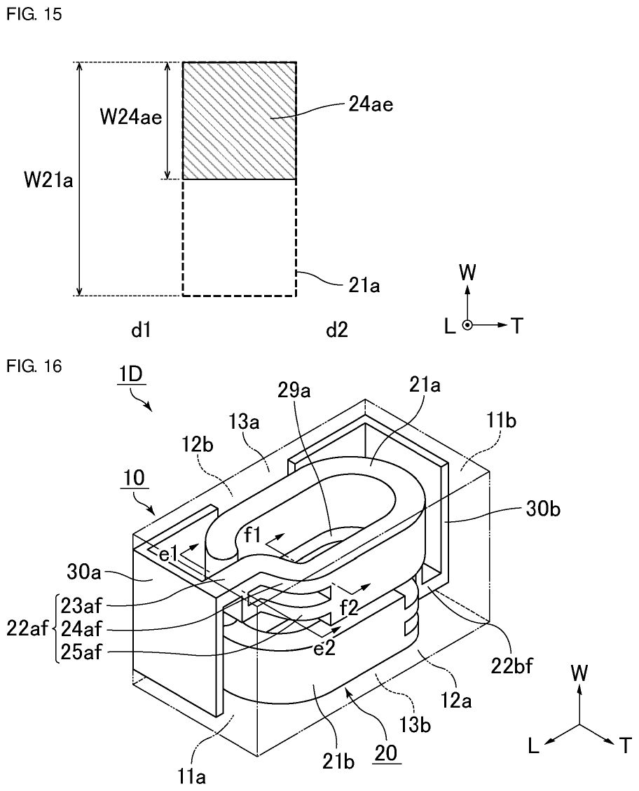

FIG. 15 is a schematic sectional view illustrating an example of a cross section along the line segment d1-d2 of the inductor component illustrated in FIG. 13. More specifically, FIG. 15 illustrates a cross section of the inductor component 1C including the boundary between the extended wire portion 24ae and the first coil wire 21a.

As illustrated in FIGS. 13, 14, and 15, the dimension of the first extended wire 22ae in the coil axial direction increases from the first outer electrode 30a side toward the first coil wire 21a side.

In the example illustrated in FIGS. 14 and 15, the dimension of the first extended wire 22ae in the coil axial direction increases stepwise from the dimension W23ae of the extended wire portion 23ae in the coil axial direction to the dimension W24ae of the extended wire portion 24ae in the coil axial direction from the first outer electrode 30a side toward the first coil wire 21a side. That is, in the example illustrated in FIGS. 14 and 15, the dimension of the first extended wire 22ae in the coil axial direction increases in two steps from the first outer electrode 30a side to the first coil wire 21a side.

The dimension of the first extended wire 22ae in the coil axial direction may increase in three or more steps from the first outer electrode 30a side toward the first coil wire 21a side.

In the examples illustrated in FIGS. 13, 14, and 15, the outer shape of the first extended wire 22ae when viewed in the height direction T is stepped on the side surface 13b side of the element body 10 so that the dimension in the coil axial direction increases stepwise from the first outer electrode 30a side to the first coil wire 21a side.

The outer shape of the first extended wire 22ae when viewed in the height direction T may be stepped on the side surface 13a side of the element body 10, or may be stepped on both sides of the side surface 13a side and the side surface 13b side of the element body 10 so that the dimension in the coil axial direction increases stepwise from the first outer electrode 30a side to the first coil wire 21a side.

The dimension of the first extended wire 22ae in the coil axial direction may gradually increase from the first outer electrode 30a side toward the first coil wire 21a side.

For example, the outer shape of the first extended wire 22ae when viewed in the height direction T may be linearly inclined on the side surface 13b side of the element body 10, may be linearly inclined on the side surface 13a side of the element body 10, may be linearly inclined on both sides of the side surface 13a and the side surface 13b of the element body 10, may be curved on the side surface 13b side of the element body 10, may be curved on the side surface 13a side of the element body 10, may be curved on both sides of the side surface 13a and the side surface 13b of the element body 10, or may be a shape combining a plurality of sets of these shapes, so as to gradually increase from the first outer electrode 30a side toward the first coil wire 21a side.

As described above, in the inductor component in which the dimension of the first extended wire in the coil axial direction increases from the first outer electrode side toward the first coil wire side, the concentration of current in the first extended wire is suppressed.

As illustrated in FIG. 13, in the inductor component 1C, the second coil wire 21b may be electrically connected to the second outer electrode 30b with the second extended wire 22be interposed therebetween. In this case, as illustrated in FIG. 13, the dimension of the second extended wire 22be in the coil axial direction may increase from the second outer electrode 30b side toward the second coil wire 21b side.

Other aspects of the second extended wire 22be are preferably the same as those of the first extended wire 22ae described above.

### Embodiment 4

In an inductor component according to Embodiment 4 of the present disclosure, the number of first extended wires increases from the first outer electrode side toward the first coil wire side. The number of extended wires is defined as the number in a cross section perpendicular to the direction where the extended wires extend. The inductor component according to Embodiment 4 of the present disclosure is the same as the inductor component according to Embodiment 1 of the present disclosure except for this point.

FIG. 16 is a schematic perspective view illustrating an example of an inductor component according to Embodiment 4 of the present disclosure.

In an inductor component 1D illustrated in FIG. 16, the first coil wire 21a is electrically connected to the first outer electrode 30a with the first extended wire 22af interposed therebetween.

The first extended wire 22af includes an extended wire portion 23af, an extended wire portion 24af, and an extended wire portion 25af.

The extended wire portion 23af is connected to the first outer electrode 30a.

The extended wire portion 24af is provided between the extended wire portion 23af and the first coil wire 21a, and is connected to both components.

The extended wire portion 25af is electrically connected to the extended wire portion 23af and the first coil wire 21a so as to be parallel to the extended wire portion 24af.

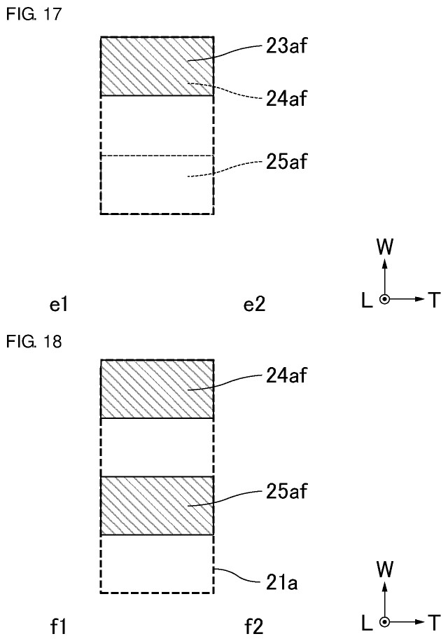

FIG. 17 is a schematic sectional view illustrating an example of a cross section along the line segment e1-e2 of the inductor component illustrated in FIG. 16. More specifically, FIG. 17 illustrates a cross section of the inductor component 1D including the boundary between the extended wire portion 23af and the extended wire portion 24af.

FIG. 18 is a schematic sectional view illustrating an example of a cross section along the line segment f1-f2 of the inductor component illustrated in FIG. 16. More specifically, FIG. 18 illustrates a cross section of the inductor component 1D including the boundary between the extended wire portion 24af (extended wire portion 25af) and the first coil wire 21a.

As illustrated in FIGS. 16, 17, and 18, the number of first extended wires 22af increases from the first outer electrode 30a side toward the first coil wire 21a side.

In the examples illustrated in FIGS. 16, 17, and 18, the number of first extended wires 22af increases from one (extended wire portion 23af) to two (extended wire portion 24af and extended wire portion 25af) from the first outer electrode 30a side toward the first coil wire 21a side.

The number of the first extended wires 22af may increase in aspects other than the aspect described above from the first outer electrode 30a side toward the first coil wire 21a side. For example, the number of first extended wires 22af may increase from one to three, or from one to two, and then from two to three from the first outer electrode 30a side toward the first coil wire 21a side. In the example described above, the number of the first extended wires 22af is one on the side closest to the first outer electrode 30a, but the number may be plural.

As described above, in an inductor component in which the number of first extended wires increases from the first outer electrode side toward the first coil wire side, current concentration in the first extended wire is suppressed.

As illustrated in FIG. 16, in the inductor component 1D, the second coil wire 21b may be electrically connected to the second outer electrode 30b with the second extended wire 22bf interposed therebetween. In this case, as illustrated in FIG. 16, the number of second extended wires 22bf may increase from the second outer electrode 30b side toward the second coil wire 21b side.

Other aspects of the second extended wire 22bf are preferably the same as those of the first extended wire 22af described above.

### Embodiment 5

In an inductor component according to Embodiment 5 of the present disclosure, both end portions of the first extended wire and both end portions of the first outer electrode are displaced from each other in the coil axial direction when viewed in the length direction orthogonal to the coil axial direction. The inductor component according to Embodiment 5 of the present disclosure is the same as the inductor component according to Embodiment 1 of the present disclosure except for this point.

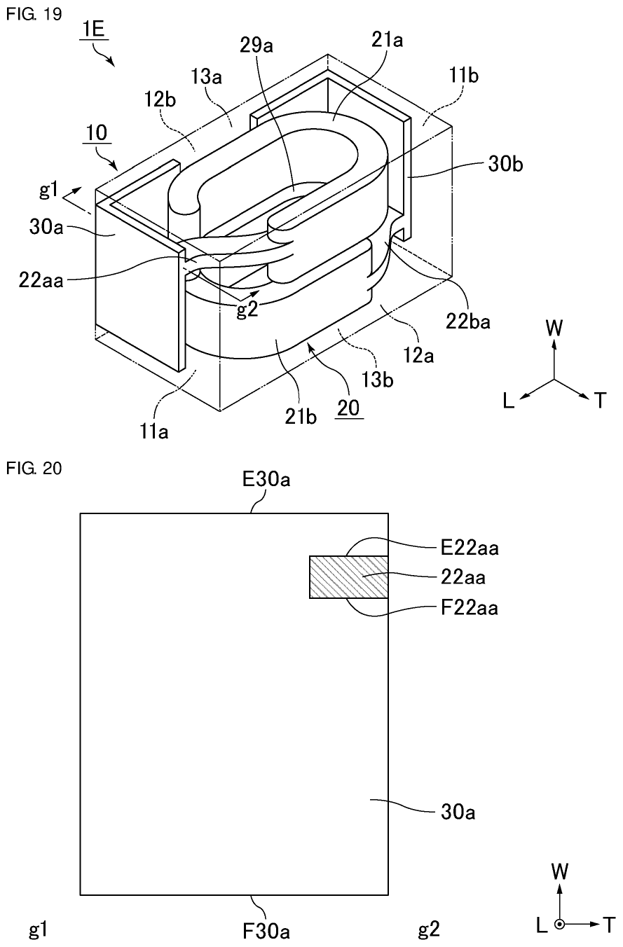

FIG. 19 is a schematic perspective view illustrating an example of an inductor component according to Embodiment 5 of the present disclosure.

FIG. 20 is a schematic sectional view illustrating an example of a cross section along the line segment g1-g2 of the inductor component illustrated in FIG. 19. More specifically, FIG. 20 illustrates a cross section of the inductor component illustrated in FIG. 19 including the boundary between the first extended wire and the first outer electrode.

In the inductor component 1E illustrated in FIG. 19, as illustrated in FIG. 20, both end portions E22aa and F22aa of the first extended wire 22aa and both end portions E30a and F30a of the first outer electrode 30a are displaced from each other in the coil axial direction when viewed in the length direction L orthogonal to the coil axial direction.

In the inductor component 1E, since both end portions E22aa and F22aa of the first extended wire 22aa and both end portions E30a and F30a of the first outer electrode 30a are displaced from each other in the coil axial direction when viewed in the length direction L, a portion where the stress is likely to remain in the vicinity of the first extended wire 22aa during firing in the manufacturing process moves away from the side surface 13a of the element body 10 and the end portion E30a of the first outer electrode 30a on the side surface 13a side of the element body 10, compared to the inductor component 1A. Therefore, in the inductor component 1E, even when an external load is applied to the side surface 13a of the element body 10 and the end portion E30a of the first outer electrode 30a on the side surface 13a side of the element body 10, interfacial delamination between the first extended wire 22aa and the element body 10 triggered by the external load is suppressed, and as a result, the occurrence of cracks is suppressed.

In FIGS. 19 and 20, although an example of an aspect in which the first coil wire 21a is electrically connected to the first outer electrode 30a with one first extended wire 22aa interposed therebetween is illustrated, an aspect in which the first coil wire 21a is electrically connected to the first outer electrode 30a with the plurality of first extended wires interposed therebetween may be used. In this case, it is preferable that each of both end portions of the first extended wire and both end portions of the first outer electrode 30a are displaced from each other in the coil axial direction when viewed in the length direction L.

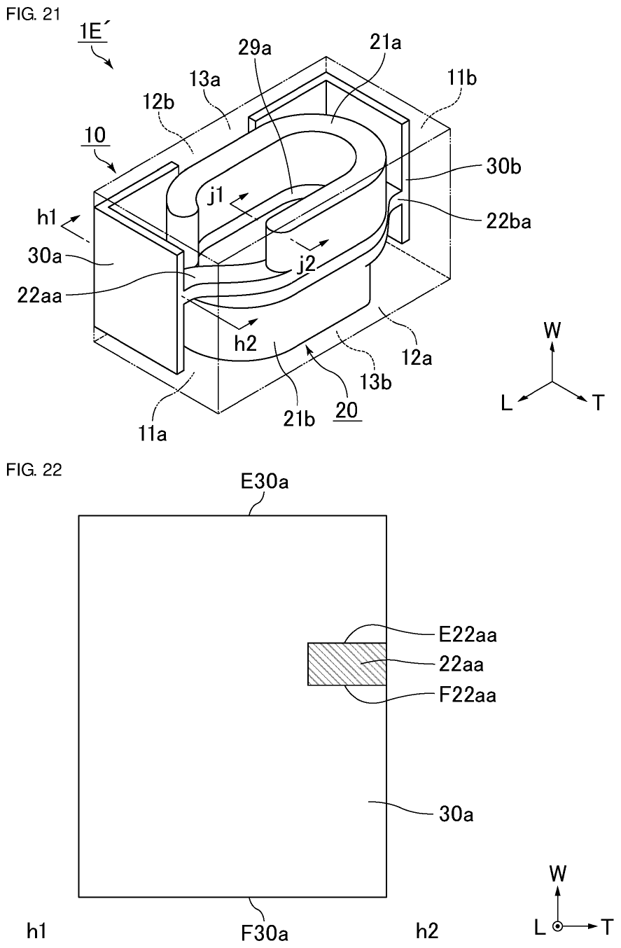

FIG. 21 is a schematic perspective view illustrating an example of an inductor component according to a modification example of Embodiment 5 of the present disclosure.

FIG. 22 is a schematic sectional view illustrating an example of a cross section along the line segment h1-h2 of the inductor component illustrated in FIG. 21. More specifically, FIG. 22 illustrates a cross section of the inductor component illustrated in FIG. 21 including the boundary between the first extended wire and the first outer electrode.

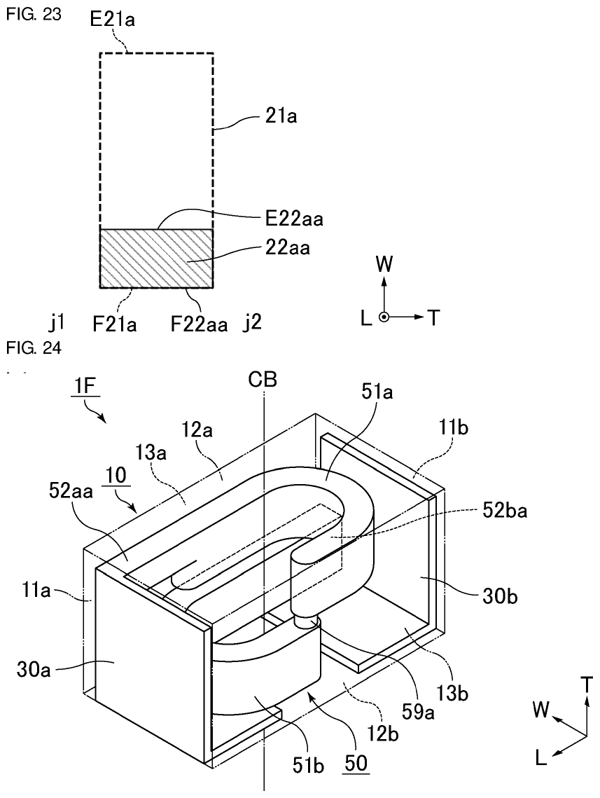

FIG. 23 is a schematic sectional view illustrating an example of a cross section along the line segment j1-j2 of the inductor component illustrated in FIG. 21. More specifically, FIG. 23 illustrates a cross section of the inductor component illustrated in FIG. 21 including the boundary between the first extended wire and the first coil wire.

In the inductor component 1E′ illustrated in FIG. 21, as illustrated in FIG. 22, both end portions E22aa and F22aa of the first extended wire 22aa and both end portions E30a and F30a of the first outer electrode 30a are displaced from each other in the coil axial direction when viewed in the length direction L.

In the inductor component 1E′ illustrated in FIG. 21, as illustrated in FIG. 23, one end portion of the first coil wire 21a (here, the end portion on the side surface 13a side of the element body 10) E21a and one end portion of the first extended wire 22aa (here, the end portion on the side surface 13a side of the element body 10) E22aa are located at different heights in the coil axial direction when viewed in the length direction L. Furthermore, in the inductor component 1E′ illustrated in FIG. 21, as illustrated in FIG. 23, when viewed in the length direction L, the other end portion (here, the end portion on the side surface 13b side of the element body 10) F21a of the first coil wire 21a located further inside the element body 10 than one end portion (here, the end portion on the side surface 13a side of the element body 10) E21a of the first coil wire 21a, that is, the other end portion (here, the end portion on the side surface 13b side of the element body 10) F21a of the first coil wire 21a having a larger distance from the surface of the element body 10 (here, the side surface 13a) than one end portion (here, the end portion on the side surface 13a side of the element body 10) E21a of the first coil wire 21a, and the other end portion (here, the end portion on the side surface 13b side of the element body 10) F22aa of the first extended wire 22aa located further inside the element body 10 than one end portion (here, the end portion on the side surface 13a side of the element body 10) E22aa of the first extended wire 22aa, that is, the other end portion (here, the end portion on the side surface 13b side of the element body 10) F22aa of the first extended wire 22aa having a larger distance from the surface of the element body 10 (here, the side surface 13a) than one end portion (here, the end portion on the side surface 13a side of the element body 10) E22aa of the first extended wire 22aa, are located at the same height in the coil axial direction.

As described above, in the inductor component 1E′, since the first extended wire 22aa separates as much as possible from the side surface 13a of the element body 10 and the end portion E30a of the first outer electrode 30a on the side surface 13a side of the element body 10 in the coil axial direction, a portion where the stress is likely to remain in the vicinity of the first extended wire 22aa during firing in the manufacturing process moves away from the side surface 13a of the element body 10 and the end portion E30a of the first outer electrode 30a on the side surface 13a side of the element body 10, compared to the inductor component 1E. Therefore, in the inductor component 1E′, even when an external load is applied to the side surface 13a of the element body 10 and the end portion E30a of the first outer electrode 30a on the side surface 13a side of the element body 10, interfacial delamination between the first extended wire 22aa and the element body 10 triggered by the external load is suppressed, and as a result, the occurrence of cracks is suppressed.

In FIGS. 21, 22, and 23, although an example of an aspect in which the first coil wire 21a is electrically connected to the first outer electrode 30a with one first extended wire 22aa interposed therebetween is illustrated, an aspect in which the first coil wire 21a is electrically connected to the first outer electrode 30a with the plurality of first extended wires interposed therebetween may be used. In this case, when viewed in the length direction L, in the coil axial direction, in a state where both end portions of each first extended wire and both end portions E30a and F30a of the first outer electrode 30a are displaced from each other, for at least one first extended wire, one end portion E21a of the first coil wire 21a and one end portion of the first extended wire are preferably located at different heights in the coil axial direction when viewed from the length direction L, and the other end portion F21a of the first coil wire 21a and the other end portion of the first extended wire are preferably located at the same height in the coil axial direction when viewed from the length direction L.

As illustrated in FIGS. 19 and 21, both end portions of the second extended wire 22ba and both end portions of the second outer electrode 30b may be displaced from each other in the coil axial direction when viewed in the length direction L. In this case, as illustrated in FIG. 21, one end portion of the second coil wire 21b (here, the end portion on the side surface 13b side of the element body 10) and one end portion of the second extended wire 22ba (here, the end portion on the side surface 13b side of the element body 10) may be located at a different height in the coil axial direction when viewed in the length direction L. Furthermore, when viewed in the length direction L, the other end portion (here, the end portion on the side surface 13a side of the element body 10) of the second coil wire 21b located further inside the element body 10 than one end portion (here, the end portion on the side surface 13b side of the element body 10) of the second coil wire 21b, that is, the other end portion (here, the end portion on the side surface 13a side of the element body 10) of the second coil wire 21b having a larger distance from the surface of the element body 10 (here, the side surface 13b) than one end portion (here, the end portion on the side surface 13b side of the element body 10) of the second coil wire 21b, and the other end portion (here, the end portion on the side surface 13a side of the element body 10) of the second extended wire 22ba located further inside the element body 10 than one end portion (here, the end portion on the side surface 13b side of the element body 10) of the second extended wire 22ba, that is, the other end portion (here, the end portion on the side surface 13a side of the element body 10) of the second extended wire 22ba having a larger distance from the surface of the element body 10 (here, the side surface 13b) than one end portion (here, the end portion on the side surface 13b side of the element body 10) of the second extended wire 22ba, may be located at the same height in the coil axial direction.

In Embodiments 1, 2, 3, 4, and 5 (modification example of Embodiment 5) described above, although an example of an aspect in which the mounting surface of the element body is parallel to the coil axial direction is described, an aspect in which the mounting surface of the element body is perpendicular to the coil axial direction may be used in these embodiments.

### Embodiment 6

In an inductor component according to Embodiment 6 of the present disclosure, the surface of the element body 10 includes a bottom surface perpendicular to the coil axial direction and a top surface facing the bottom surface in the coil axial direction, and the bottom surface of the element body is a mounting surface. Furthermore, in the inductor component according to Embodiment 6 of the present disclosure, the plurality of coil wires further include a second coil wire electrically connected to the second outer electrode with one or a plurality of second extended wires interposed therebetween, the first extended wire is located further toward the top surface side of the element body than the second extended wire in the coil axial direction, and the dimension of each of the one or the plurality of first extended wires in the coil axial direction is smaller than the dimension of each of the one or the plurality of second extended wires in the coil axial direction. The inductor component according to Embodiment 6 of the present disclosure is the same as the inductor component according to Embodiment 1 of the present disclosure except for this point.

FIG. 24 is a schematic perspective view illustrating an example of an inductor component according to Embodiment 6 of the present disclosure.

An inductor component 1F illustrated in FIG. 24 includes the element body 10, a coil 50, the first outer electrode 30a, and the second outer electrode 30b.

As illustrated in FIG. 24, in the inductor component 1F, the surfaces of the element body 10 include an end surface 11a and an end surface 11b facing each other in the length direction L, a top surface 12a and a bottom surface 12b facing each other in the height direction T, and a side surface 13a and a side surface 13b facing each other in the width direction W. In inductor component 1F, the height direction T is parallel to the coil axial direction of the coil 50. That is, in the inductor component 1F, the surface of the element body 10 includes the bottom surface 12b perpendicular to the coil axial direction and the top surface 12a facing the bottom surface 12b in the coil axial direction.

In the present embodiment, the coil axial direction is the direction parallel to the height direction T unless otherwise specified.

In inductor component 1F, the bottom surface 12b of the element body 10 is a mounting surface. More specifically, the bottom surface 12b of the element body 10 is a mounting surface that faces an object to be mounted (for example, substrate) when the inductor component 1F is mounted. Therefore, in the inductor component 1F, the mounting surface of the element body 10, that is, the bottom surface 12b of the element body 10 is perpendicular to the coil axial direction.

As illustrated in FIG. 24, the coil 50 is provided inside the element body 10 and is spirally wound along the coil axial direction.

The coil axial direction of the coil 50 is the direction where a coil axis CB of the coil 50 extends, and is perpendicular to the bottom surface 12b, which is the mounting surface of the element body 10, as described above.

As illustrated in FIG. 24, the coil 50 is formed by electrically connecting a plurality of coil wires laminated in the coil axial direction.

In the example illustrated in FIG. 24, the plurality of coil wires include a first coil wire 51a and a second coil wire 51b.

The first coil wire 51a is present at the outermost position on the top surface 12a side of the element body 10 in the coil axial direction among the plurality of coil wires.

The second coil wire 51b is present at the outermost position on the bottom surface 12b side of the element body 10 in the coil axial direction among the plurality of coil wires.

In the example illustrated in FIG. 24, the first coil wire 51a and the second coil wire 51b are electrically connected with a connection conductor 59a penetrating an insulating layer present between both wires in the coil axial direction interposed therebetween.

As illustrated in FIG. 24, the first outer electrode 30a is electrically connected to one end portion of the coil 50. More specifically, the first coil wire 51a constituting the coil 50 is electrically connected to the first outer electrode 30a with one first extended wire 52aa interposed therebetween.

As illustrated in FIG. 24, the first outer electrode 30a extends from a part of the bottom surface 12b to a part of the end surface 11a of the element body 10. That is, the first outer electrode 30a is exposed on a part of the end surface 11a of the element body 10, in addition to a part of the bottom surface 12b of the element body 10.

As illustrated in FIG. 24, the second outer electrode 30b is electrically connected to the other end portion of the coil 50. More specifically, the second coil wire 51b constituting the coil 50 is electrically connected to the second outer electrode 30b with one second extended wire 52ba interposed therebetween.

As illustrated in FIG. 24, the second outer electrode 30b extends from a part of the bottom surface 12b to a part of the end surface 11b of the element body 10. That is, the second outer electrode 30b is exposed on a part of the end surface 11b of the element body 10, in addition to a part of the bottom surface 12b of the element body 10.

As illustrated in FIG. 24, the first extended wire 52aa is located further toward the top surface 12a side of the element body 10 than the second extended wire 52ba in the coil axial direction.

As illustrated in FIG. 24, the dimension of the first extended wire 52aa in the coil axial direction is smaller than the dimension of the second extended wire 52ba in the coil axial direction.

In the inductor component 1F, since the dimension of the first extended wire 52aa in the coil axial direction is smaller than the dimension of the second extended wire 52ba in the coil axial direction, residual stress in the vicinity of the first extended wire 52aa during firing in the manufacturing process is suppressed. Therefore, in the inductor component 1F, even when an external load is applied to the element body 10 and the first outer electrode 30a in the vicinity of the first extended wire 52aa, interfacial delamination between the first extended wire 52aa and the element body 10 triggered by the external load is suppressed, and as a result, the occurrence of cracks is suppressed.

In FIG. 24, although an example of an aspect in which the first coil wire 51a is electrically connected to the first outer electrode 30a with one first extended wire 52aa interposed therebetween, and the second coil wire 51b is electrically connected to the second outer electrode 30b with one second extended wire 52ba interposed therebetween, and an aspect in which the first coil wire 51a is electrically connected to the first outer electrode 30a with the plurality of first extended wires interposed therebetween is illustrated, the second coil wire 51b is electrically connected to the second outer electrode 30b with the plurality of second extended wires interposed therebetween may be used. That is, the first coil wire 51a may be electrically connected to the first outer electrode 30a with one or a plurality of first extended wires interposed therebetween, and the second coil wire 51b may be electrically connected to the second outer electrode 30b with one or a plurality of second extended wires interposed therebetween. In this case, the dimension of each of the one or the plurality of first extended wires in the coil axial direction may be smaller than the dimension of each of the one or the plurality of second extended wires in the coil axial direction. In other words, the maximum value of the dimension of all the first extended wires in the coil axial direction may be smaller than the minimum value of the dimension of all the second extended wires in the coil axial direction.

In a second aspect, an inductor component of the present disclosure includes an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body, the element body includes an insulator, the coil is formed by electrically connecting a plurality of coil wires laminated in the coil axial direction, the plurality of coil wires include a first coil wire electrically connected to the first outer electrode with at least one first extended wire interposed therebetween, and when viewed in a length direction orthogonal to the coil axial direction, both end portions of the first extended wire and both end portions of the first outer electrode are displaced from each other in the coil axial direction.

### Embodiment 7

An example of the second aspect of the inductor component of the present disclosure will be described below as an inductor component according to Embodiment 7 of the present disclosure.

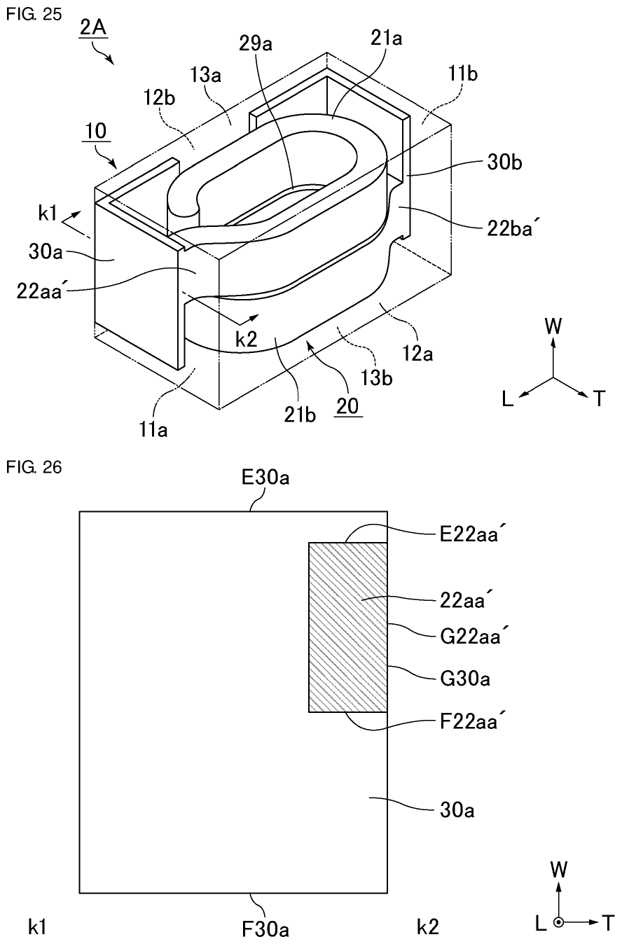

FIG. 25 is a schematic perspective view illustrating an example of the inductor component according to Embodiment 7 of the present disclosure.

An inductor component 2A illustrated in FIG. 25 includes the element body 10, the coil 20, the first outer electrode 30a, and the second outer electrode 30b.

Each of the element body 10, the coil 20, the first outer electrode 30a, and the second outer electrode 30b that constitute the inductor component 2A are the same as the element body 10, the coil 20, the first outer electrode 30a, and the second outer electrode 30b that constitute the inductor component 1A described above.

In the present embodiment, the coil axial direction is a direction parallel to the width direction W unless otherwise specified.

As illustrated in FIG. 25, the first outer electrode 30a is electrically connected to one end portion of the coil 20. More specifically, as illustrated in FIG. 25, the first coil wire 21a constituting the coil 20 is electrically connected to the first outer electrode 30a with the first extended wire 22aa′ interposed therebetween.

As illustrated in FIG. 25, it is preferable that the dimension of the first extended wire 22aa′ in the coil axial direction is the same as the dimension of the first coil wire 21a in the coil axial direction.

In the inductor component 2A, since the dimension of the first extended wire 22aa′ in the coil axial direction is the same as the dimension of the first coil wire 21a in the coil axial direction, an increase in DC resistance is suppressed compared to the inductor component 1A.

FIG. 26 is a schematic sectional view illustrating an example of a cross section along the line segment k1-k2 of the inductor component illustrated in FIG. 25. More specifically, FIG. 26 illustrates a cross section of the inductor component 2A including the boundary between the first extended wire 22aa′ and the first outer electrode 30a.

As illustrated in FIG. 26, both end portions E22aa′ and F22aa′ of the first extended wire 22aa′ and both end portions E30a and F30a of the first outer electrode 30a are displaced from each other in the coil axial direction when viewed in the length direction L orthogonal to the coil axial direction.

In the inductor component 2A, since both end portions E22aa′ and F22aa′ of the first extended wire 22aa′ and both end portions E30a and F30a of the first outer electrode 30a are displaced from each other in the coil axial direction when viewed in the length direction L, a portion where the stress is likely to remain in the vicinity of the first extended wire 22aa′ during firing in the manufacturing process moves away from the side surface 13a of the element body 10 and the end portion E30a of the first outer electrode 30a on the side surface 13a side of the element body 10, compared to the inductor component 1A. Therefore, in the inductor component 2A, even when an external load is applied to the side surface 13a of the element body 10 and the end portion E30a of the first outer electrode 30a on the side surface 13a side of the element body 10, interfacial delamination between the first extended wire 22aa′ and the element body 10 triggered by the external load is suppressed, and as a result, the occurrence of cracks is suppressed.

As illustrated in FIG. 26, when viewed in the length direction L orthogonal to the coil axial direction, one end portion G22aa of the first extended wire 22aa′ and one end portion G30a of the first outer electrode 30a are located at the same position in the height direction T orthogonal to the coil axial direction and to the length direction L. As a result, stray capacitance between the first extended wire 22aa′ and the first outer electrode 30a is suppressed.

As illustrated in FIG. 25, the second outer electrode 30b is electrically connected to the other end portion of the coil 20. More specifically, as illustrated in FIG. 25, the second coil wire 21b constituting the coil 20 may be electrically connected to the second outer electrode 30b with a second extended wire 22ba′ interposed therebetween.

As illustrated in FIG. 25, it is preferable that the dimension of the second extended wire 22ba′ in the coil axial direction is the same as the dimension of the second coil wire 21b in the coil axial direction.

As illustrated in FIG. 25, it is preferable that both end portions of the second extended wire 22ba′ and both end portions of the second outer electrode 30b are displaced from each other in the coil axial direction when viewed in the length direction L.

In FIG. 25, although an example of an aspect in which the mounting surface of the element body is parallel to the coil axial direction is illustrated, an aspect in which the mounting surface of the element body is perpendicular to the coil axial direction may be used.

Each of the other aspects of the first extended wire 22aa′ and the second extended wire 22ba′ are preferably the same as the above-described Embodiments 1, 2, 3, 4, and 5 (modification example of Embodiment 5), and the first extended wire and the second extended wire of Embodiment 6.

In the inductor component 2A, a configuration in which both end portions E22aa′ and F22aa′ of the first extended wire 22aa′ and both end portions E30a and F30a of the first outer electrode 30a are displaced from each other when viewed from the length direction L, in the coil axial direction, is realized, for example, by reducing the dimension of the insulating layer between the first coil wire 21a and the second coil wire 21b in the coil axial direction, or by increasing the dimension of the first outer electrode 30a in the coil axial direction, with respect to an inductor component in which the dimension of the first coil wire 21a in the coil axial direction and the dimension of the first extended wire 22aa′ in the coil axial direction are the same as each other. A configuration in which both end portions of the second extended wire 22ba′ and both end portions of the second outer electrode 30b are displaced from each other in the coil axial direction when viewed in the length direction L is also realized in the same manner.

In a third aspect, an inductor component of the present disclosure includes an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body, the element body includes an insulator, the surface of the element body includes a bottom surface perpendicular to the coil axial direction and a top surface facing the bottom surface in the coil axial direction, the first outer electrode and the second outer electrode are exposed so as to be separated from each other at least on the bottom surface of the element body, the coil is formed by electrically connecting a plurality of coil wires laminated in the coil axial direction, the plurality of coil wires include a first coil wire electrically connected to the first outer electrode with at least one first extended wire interposed therebetween and a second coil wire electrically connected to the second outer electrode with at least one second extended wire interposed therebetween, the first extended wire is located further toward the top surface side of the element body than the second extended wire in the coil axial direction, and when viewed in a length direction orthogonal to the coil axial direction, a minimum distance between an end portion of the first extended wire and an end portion of the first outer electrode is larger than a minimum distance between an end portion of the second extended wire and an end portion of the second outer electrode in a width direction orthogonal to the coil axial direction and to the length direction.

### Embodiment 8

An example of the third aspect of the inductor component of the present disclosure will be described below as an inductor component according to Embodiment 8 of the present disclosure.

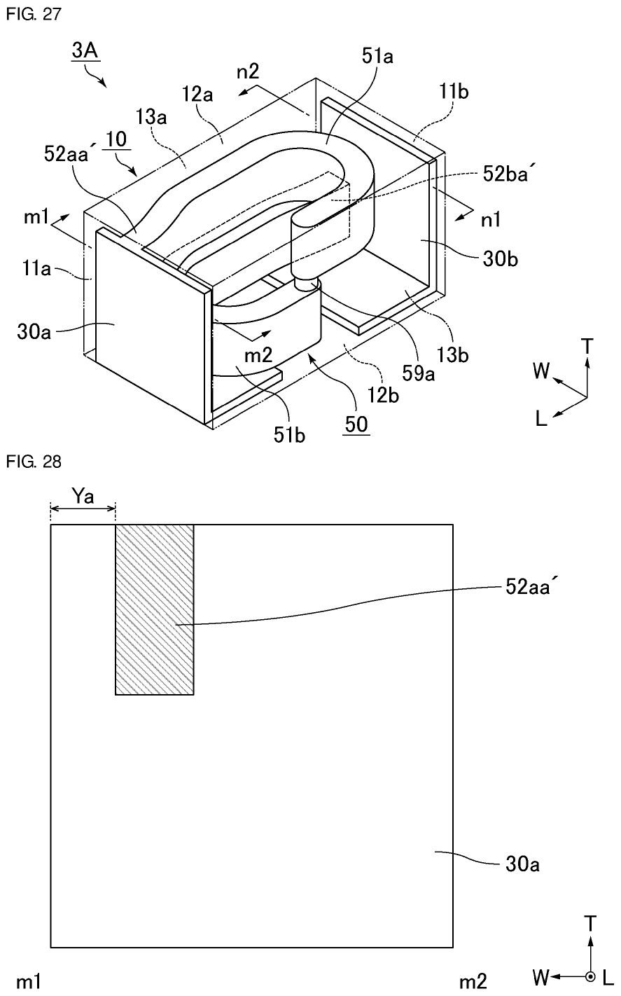

FIG. 27 is a schematic perspective view illustrating an example of an inductor component according to Embodiment 8 of the present disclosure.

An inductor component 3A illustrated in FIG. 27 includes the element body 10, the coil 50, the first outer electrode 30a, and the second outer electrode 30b.

Each of the element body 10, the coil 50, the first outer electrode 30a, and the second outer electrode 30b that constitute the inductor component 3A are the same as the element body 10, the coil 50, the first outer electrode 30a, and the second outer electrode 30b that constitute the inductor component 1F described above.

In the present embodiment, the coil axial direction is the direction parallel to the height direction T unless otherwise specified.

As illustrated in FIG. 27, the first outer electrode 30a is electrically connected to one end portion of the coil 50. More specifically, as illustrated in FIG. 27, the first coil wire 51a constituting the coil 50 is electrically connected to the first outer electrode 30a with the first extended wire 52aa′ interposed therebetween.

As illustrated in FIG. 27, it is preferable that the dimension of the first extended wire 52aa′ in the coil axial direction is the same as the dimension of the first coil wire 51a in the coil axial direction.

In the inductor component 3A, since the dimension of the first extended wire 52aa′ in the coil axial direction is the same as the dimension of the first coil wire 51a in the coil axial direction, an increase in DC resistance is suppressed compared to the inductor component 1F.

As illustrated in FIG. 27, the second outer electrode 30b is electrically connected to the other end portion of the coil 50. More specifically, as illustrated in FIG. 27, the second coil wire 51b constituting the coil 50 is electrically connected to the second outer electrode 30b with the second extended wire 52ba′ interposed therebetween.

As illustrated in FIG. 27, it is preferable that the dimension of the second extended wire 52ba′ in the coil axial direction is the same as the dimension of the second coil wire 51b in the coil axial direction.

As illustrated in FIG. 27, the first extended wire 52aa′ is located further toward the top surface 12a side of the element body 10 than the second extended wire 52ba′ in the coil axial direction.

FIG. 28 is a schematic sectional view illustrating an example of a cross section along the line segment m1-m2 of the inductor component illustrated in FIG. 27. More specifically, FIG. 28 illustrates a cross section of the inductor component 3A including the boundary between the first extended wire 52aa′ and the first outer electrode 30a.

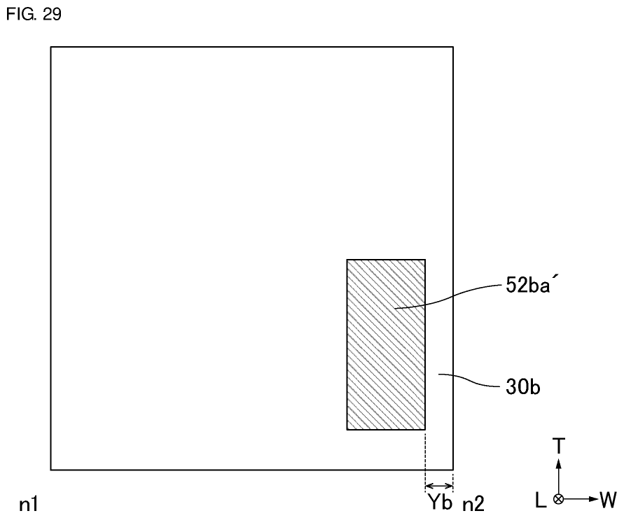

FIG. 29 is a schematic sectional view illustrating an example of a cross section along the line segment n1-n2 of the inductor component illustrated in FIG. 27. More specifically, FIG. 29 illustrates a cross section of the inductor component 3A including the boundary between the second extended wire 52ba′ and the second outer electrode 30b.

As illustrated in FIGS. 28 and 29, when viewed in the length direction L orthogonal to the coil axial direction, the minimum distance Ya between the end portion of the first extended wire 52aa′ and the end portion of the first outer electrode 30a is larger than the minimum distance Yb between the end portion of the second extended wire 52ba′ and the end portion of the second outer electrode 30b in the width direction W orthogonal to the coil axial direction and to the length direction L.

In the inductor component 3A, since the minimum distance Ya between the end portion of the first extended wire 52aa′ and the end portion of the first outer electrode 30a is larger than the minimum distance Yb between the end portion of the second extended wire 52ba′ and the end portion of the second outer electrode 30b in the width direction W when viewed in the length direction L, a portion where the stress is likely to remain in the vicinity of the first extended wire 52aa′ during firing in the manufacturing process moves away from the side surface 13a of the element body 10 and the end portion of the first outer electrode 30a on the side surface 13a side of the element body 10, compared to the inductor component 1F. Therefore, in the inductor component 3A, even when an external load is applied to the side surface 13a of the element body 10 and the end portion of the first outer electrode 30a on the side surface 13a side of the element body 10, interfacial delamination between the first extended wire 52aa′ and the element body 10 triggered by the external load is suppressed, and as a result, the occurrence of cracks is suppressed.

Each of the other aspects of the first extended wire 52aa′ and the second extended wire 52ba′ are preferably the same as the above-described Embodiments 1, 2, 3, 4, and 5 (modification example of Embodiment 5), and the first extended wire and the second extended wire of Embodiment 6.

In the inductor component 3A, a configuration in which the minimum distance Ya between the end portion of the first extended wire 52aa′ and the end portion of the first outer electrode 30a is larger than the minimum distance Yb between the end portion of the second extended wire 52ba′ and the end portion of the second outer electrode 30b, in the width direction W when viewed from the length direction L, is realized, for example, by bending the first extended wire 52aa′ further toward the side surface 13b side of the element body 10 than the second extended wire 52ba′ or expanding the first outer electrode 30a further toward the side surface 13a side of the element body 10 than the second outer electrode 30b, with respect to a configuration in which the dimension of the first coil wire 51a in the coil axial direction and the dimension of the first extended wire 52aa of the inductor component 1F in the coil axial direction are the same as each other.

The following contents are disclosed in this specification.

<1> An inductor component including an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body. The element body has an insulator. The coil is formed by electrically connecting a plurality of coil wires laminated in the coil axial direction. The plurality of coil wires include a first coil wire electrically connected to the first outer electrode with one or a plurality of first extended wires interposed therebetween. A dimension of each of the one or the plurality of first extended wires in the coil axial direction is smaller than a dimension of the first coil wire in the coil axial direction.

<2> The inductor component according to <1>, in which the first coil wire is electrically connected to the first outer electrode with the plurality of first extended wires arranged in the coil axial direction interposed therebetween.

<3> The inductor component according to <2>, in which the plurality of first extended wires each have an identical dimension in the coil axial direction.

<4> The inductor component according to <2>, in which the plurality of first extended wires include a first outer side portion extended wire and a first inner side portion extended wire located further inside the element body than the first outer side portion extended wire in the coil axial direction, and a dimension of the first outer side portion extended wire in the coil axial direction and a dimension of the first inner side portion extended wire in the coil axial direction are different from each other.

<5> The inductor component according to <4>, in which the dimension of the first outer side portion extended wire in the coil axial direction is smaller than the dimension of the first inner side portion extended wire in the coil axial direction.

<6> The inductor component according to any one of <2> to <5>, in which the plurality of first extended wires include three or more first extended wires, and intervals between the plurality of first extended wires in the coil axial direction are the same as each other.

<7> The inductor component according to any one of <2> to <5>, in which the plurality of first extended wires include a first outer side portion extended wire, a first inner side portion extended wire located further inside the element body than the first outer side portion extended wire in the coil axial direction, and a first intermediate portion extended wire located between the first outer side portion extended wire and the first inner side portion extended wire so as to be adjacent to both the first outer side portion extended wire and the first inner side portion extended wire in the coil axial direction. Also, an interval between the first outer side portion extended wire and the first intermediate portion extended wire in the coil axial direction and an interval between the first inner side portion extended wire and the first intermediate portion extended wire in the coil axial direction are different from each other.

<8> The inductor component according to <7>, in which the interval between the first outer side portion extended wire and the first intermediate portion extended wire in the coil axial direction is larger than the interval between the first inner side portion extended wire and the first intermediate portion extended wire in the coil axial direction.

<9> The inductor component according to any one of <2> to <8>, in which the plurality of first extended wires include a first outer side portion extended wire and a first inner side portion extended wire located further inside the element body than the first outer side portion extended wire in the coil axial direction. When viewed in a length direction orthogonal to the coil axial direction, one end portion of the first coil wire and an end portion of the first outer side portion extended wire opposite to the first inner side portion extended wire are located at the same height in the coil axial direction. Also, when viewed in the length direction, the other end portion of the first coil wire located further inside the element body than the one end portion of the first coil wire and an end portion of the first inner side portion extended wire opposite to the first outer side portion extended wire are located at the same height in the coil axial direction.

<10> The inductor component according to any one of <1> to <9>, in which the dimension of the first extended wire in the coil axial direction increases from the first outer electrode side toward the first coil wire side.

<11> The inductor component according to any one of <1> to <9>, in which the number of the first extended wires increases from the first outer electrode side toward the first coil wire side.

<12> The inductor component according to any one of <1> to <11>, in which when viewed in a length direction orthogonal to the coil axial direction, both end portions of the first extended wire and both end portions of the first outer electrode are displaced from each other in the coil axial direction.

<13> The inductor component according to <12>, in which when viewed in the length direction, one end portion of the first coil wire and one end portion of the first extended wire are located at different heights from each other in the coil axial direction, and when viewed in the length direction, the other end portion of the first coil wire located further inside the element body than the one end portion of the first coil wire and the other end portion of the first extended wire located further inside the element body than the one end portion of the first extended wire are located at the same height in the coil axial direction.

<14> The inductor component according to any one of <1> to <13>, in which the first coil wire and the first extended wire are connected at a corner portion corresponding to a portion where the first extended wire begins to extend obliquely from a linear portion of the first coil wire when viewed in the coil axial direction.

<15> The inductor component according to any one of <1> to <14>, in which the surface of the element body includes a bottom surface parallel to the coil axial direction and a top surface facing the bottom surface in a height direction orthogonal to the coil axial direction, and the first outer electrode and the second outer electrode are exposed so as to be separated from each other at least on the bottom surface of the element body.

<16> The inductor component according to any one of <1> to <14>, in which the surface of the element body includes a bottom surface perpendicular to the coil axial direction and a top surface facing the bottom surface in the coil axial direction, and the first outer electrode and the second outer electrode are exposed so as to be separated from each other at least on the bottom surface of the element body.

<17> The inductor component according to <16>, in which the plurality of coil wires further include a second coil wire electrically connected to the second outer electrode with one or a plurality of second extended wires interposed therebetween. The first extended wire is located further toward the top surface side of the element body than the second extended wire in the coil axial direction, and the dimension of each of the one or the plurality of first extended wires in the coil axial direction is smaller than a dimension of each of the one or the plurality of second extended wires in the coil axial direction.

<18> An inductor component including an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body. The element body has an insulator. The coil is formed by electrically connecting a plurality of coil wires laminated in the coil axial direction. The plurality of coil wires include a first coil wire electrically connected to the first outer electrode with one or a plurality of first extended wires interposed therebetween, and when viewed in a length direction orthogonal to the coil axial direction, both end portions of the first extended wire and both end portions of the first outer electrode are displaced from each other in the coil axial direction.

<19> An inductor component including an element body, a coil provided inside the element body and spirally wound along a coil axial direction, a first outer electrode electrically connected to one end portion of the coil and exposed on a surface of the element body, and a second outer electrode electrically connected to the other end portion of the coil and exposed on the surface of the element body. The element body has an insulator. The surface of the element body includes a bottom surface perpendicular to the coil axial direction and a top surface facing the bottom surface in the coil axial direction. The first outer electrode and the second outer electrode are exposed so as to be separated from each other at least on the bottom surface of the element body. The coil is formed by electrically connecting a plurality of coil wires laminated in the coil axial direction. The plurality of coil wires include a first coil wire electrically connected to the first outer electrode with one or a plurality of first extended wires interposed therebetween and a second coil wire electrically connected to the second outer electrode with one or a plurality of second extended wires interposed therebetween. The first extended wire is located further toward the top surface side of the element body than the second extended wire in the coil axial direction. When viewed in a length direction orthogonal to the coil axial direction, a minimum distance between an end portion of the first extended wire and an end portion of the first outer electrode is larger than a minimum distance between an end portion of the second extended wire and an end portion of the second outer electrode in a width direction orthogonal to the coil axial direction and to the length direction.

<20> The inductor component according to <1>, in which the first coil wire is electrically connected to the first outer electrode with the one first extended wire interposed therebetween.

<21> The inductor component according to <4>, in which the dimension of the first inner side portion extended wire in the coil axial direction is smaller than the dimension of the first outer side portion extended wire in the coil axial direction.

<22> The inductor component according to <7>, in which the interval between the first inner side portion extended wire and the first intermediate portion extended wire in the coil axial direction is larger than the interval between the first outer side portion extended wire and the first intermediate portion extended wire in the coil axial direction.

<23> The inductor component according to <18>, in which the dimension of each of the one or the plurality of first extended wires in the coil axial direction is smaller than the dimension of the first coil wire in the coil axial direction.

<24> The inductor component according to <18> or <23>, in which the first coil wire is electrically connected to the first outer electrode with the one first extended wire interposed therebetween.

<25> The inductor component according to <18> or <23>, in which the first coil wire is electrically connected to the first outer electrode with the plurality of first extended wires arranged in the coil axial direction interposed therebetween.

<26> The inductor component according to <25>, in which the dimensions of the plurality of first extended wires in the coil axial direction are the same as each other.

<27> The inductor component according to <25>, in which the plurality of first extended wires include a first outer side portion extended wire and a first inner side portion extended wire located further inside the element body than the first outer side portion extended wire in the coil axial direction, and the dimension of the first outer side portion extended wire in the coil axial direction and the dimension of the first inner side portion extended wire in the coil axial direction are different from each other.

<28> The inductor component according to <27>, in which the dimension of the first outer side portion extended wire in the coil axial direction is smaller than the dimension of the first inner side portion extended wire in the coil axial direction.

<29> The inductor component according to <27>, in which the dimension of the first inner side portion extended wire in the coil axial direction is smaller than the dimension of the first outer side portion extended wire in the coil axial direction.

<30> The inductor component according to any one of <25> to <29>, in which the plurality of first extended wires include three or more first extended wires, and the intervals between the plurality of first extended wires in the coil axial direction are the same as each other.

<31> The inductor component according to any one of <25> to <29>, in which the plurality of first extended wires include a first outer side portion extended wire, a first inner side portion extended wire located further inside the element body than the first outer side portion extended wire in the coil axial direction, and a first intermediate portion extended wire located between the first outer side portion extended wire and the first inner side portion extended wire so as to be adjacent to the first outer side portion extended wire and the first inner side portion extended wire in the coil axial direction. Also, the interval between the first outer side portion extended wire and the first intermediate portion extended wire in the coil axial direction and the interval between the first inner side portion extended wire and the first intermediate portion extended wire in the coil axial direction are different from each other.

<32> The inductor component according to <31>, in which the interval between the first outer side portion extended wire and the first intermediate portion extended wire in the coil axial direction is larger than the interval between the first inner side portion extended wire and the first intermediate portion extended wire in the coil axial direction.

<33> The inductor component according to <31>, in which the interval between the first inner side portion extended wire and the first intermediate portion extended wire in the coil axial direction is larger than the interval between the first outer side portion extended wire and the first intermediate portion extended wire in the coil axial direction.

<34> The inductor component according to any one of <25> to <33>, in which the plurality of first extended wires include a first outer side portion extended wire and a first inner side portion extended wire located further inside the element body than the first outer side portion extended wire in the coil axial direction. When viewed in a length direction orthogonal to the coil axial direction, one end portion of the first coil wire and an end portion of the first outer side portion extended wire opposite to the first inner side portion extended wire are located at the same height in the coil axial direction. Also, when viewed in the length direction, the other end portion of the first coil wire located further inside the element body than the one end portion of the first coil wire and an end portion of the first inner side portion extended wire opposite to the first outer side portion extended wire are located at the same height in the coil axial direction.

<35> The inductor component according to any one of <18> and <23> to <34>, in which the dimension of the first extended wire in the coil axial direction increases from the first outer electrode side toward the first coil wire side.

<36> The inductor component according to any one of <18>, <23>, and <25> to <34>, in which the number of the first extended wires increases from the first outer electrode side toward the first coil wire side.

<37> The inductor component according to any one of <18> and <23> to <36>, in which when viewed in the length direction, one end portion of the first coil wire and one end portion of the first extended wire are located at different heights in the coil axial direction. When viewed in the length direction, the other end portion of the first coil wire located further inside the element body than the one end portion of the first coil wire and the other end portion of the first extended wire located further inside the element body than the one end portion of the first extended wire are located at the same height in the coil axial direction.

<38> The inductor component according to any one of <18> and <23> to <37>, in which the first coil wire and the first extended wire are connected at a corner portion corresponding to a portion where the first extended wire begins to extend obliquely from the linear portion of the first coil wire when viewed in the coil axial direction.

<39> The inductor component according to any one of <18> and <23> to <38>, in which the surface of the element body includes a bottom surface parallel to the coil axial direction and a top surface facing the bottom surface in a height direction orthogonal to the coil axial direction, and the first outer electrode and the second outer electrode are exposed so as to be separated from each other at least on the bottom surface of the element body.

<40> The inductor component according to any one of <18> and <23> to <38>, in which the surface of the element body includes a bottom surface perpendicular to the coil axial direction and a top surface facing the bottom surface in the coil axial direction, and the first outer electrode and the second outer electrode are exposed so as to be separated from each other at least on the bottom surface of the element body.

<41> The inductor component according to <40>, in which the plurality of coil wires further include a second coil wire electrically connected to the second outer electrode with one or a plurality of second extended wires interposed therebetween. The first extended wire is located further toward the top surface side of the element body than the second extended wire in the coil axial direction, and the dimension of each of the one or the plurality of first extended wires in the coil axial direction is smaller than the dimension of each of the one or the plurality of second extended wires in the coil axial direction.

<42> The inductor component according to <19>, in which the dimension of each of the one or the plurality of first extended wires in the coil axial direction is smaller than the dimension of the first coil wires in the coil axial direction.

<43> The inductor component according to <19> or <42>, in which the first coil wire is electrically connected to the first outer electrode with the one first extended wire interposed therebetween.

<44> The inductor component according to <19> or <42>, in which the first coil wire is electrically connected to the first outer electrode with the plurality of first extended wires arranged in the coil axial direction interposed therebetween.

<45> The inductor component according to <44>, in which the dimensions of the plurality of first extended wires in the coil axial direction are the same as each other.

<46> The inductor component according to <44>, in which the plurality of first extended wires include a first outer side portion extended wire and a first inner side portion extended wire located further inside the element body than the first outer side portion extended wire in the coil axial direction, and the dimension of the first outer side portion extended wire in the coil axial direction and the dimension of the first inner side portion extended wire in the coil axial direction are different from each other.

<47> The inductor component according to <46>, in which the dimension of the first inner side portion extended wire in the coil axial direction is smaller than the dimension of the first outer side portion extended wire in the coil axial direction.

<48> The inductor component according to <46>, in which the dimension of the first inner side portion extended wire in the coil axial direction is smaller than the dimension of the first outer side portion extended wire in the coil axial direction.

<49> The inductor component according to any one of <44> to <48>, in which the plurality of first extended wires include three or more first extended wires, and the intervals between the plurality of first extended wires in the coil axial direction are the same as each other.

<50> The inductor component according to any one of <44> to <48> in which the plurality of first extended wires include a first outer side portion extended wire, a first inner side portion extended wire located further inside the element body than the first outer side portion extended wire in the coil axial direction, and a first intermediate portion extended wire located between the first outer side portion extended wire and the first inner side portion extended wire so as to be adjacent to the first outer side portion extended wire and the first inner side portion extended wire in the coil axial direction. The interval between the first outer side portion extended wire and the first intermediate portion extended wire in the coil axial direction and the interval between the first inner side portion extended wire and the first intermediate portion extended wire in the coil axial direction are different from each other.

<51> The inductor component according to <50>, in which the interval between the first outer side portion extended wire and the first intermediate portion extended wire in the coil axial direction is larger than the interval between the first inner side portion extended wire and the first intermediate portion extended wire in the coil axial direction.

<52> The inductor component according to <50>, in which the interval between the first inner side portion extended wire and the first intermediate portion extended wire in the coil axial direction is larger than the interval between the first outer side portion extended wire and the first intermediate portion extended wire in the coil axial direction.

<53> The inductor component according to any one of <44> to <52>, in which the plurality of first extended wires include a first outer side portion extended wire and a first inner side portion extended wire located further inside the element body than the first outer side portion extended wire in the coil axial direction. When viewed in a length direction orthogonal to the coil axial direction, one end portion of the first coil wire and an end portion of the first outer side portion extended wire opposite to the first inner side portion extended wire are located at the same height in the coil axial direction. When viewed in the length direction, the other end portion of the first coil wire located further inside the element body than the one end portion of the first coil wire and an end portion of the first inner side portion extended wire opposite to the first outer side portion extended wire are located at the same height in the coil axial direction.

<54> The inductor component according to any one of <19> and <42> to <53>, in which the dimension of the first extended wire in the coil axial direction increases from the first outer electrode side toward the first coil wire side.

<55> The inductor component according to any one of <19>, <42>, and <44> to <53>, in which the number of the first extended wires increases from the first outer electrode side toward the first coil wire side.

<56> The inductor component according to any one of <19> and <42> to <55>, in which when viewed in the length direction orthogonal to the coil axial direction, both end portions of the first extended wire and both end portions of the first outer electrode are displaced from each other in the coil axial direction.

<57> The inductor component according to <56>, in which when viewed in the length direction, one end portion of the first coil wire and one end portion of the first extended wire are located at different heights in the coil axial direction. When viewed in the length direction, the other end portion of the first coil wire located further inside the element body than the one end portion of the first coil wire and the other end portion of the first extended wire located further inside the element body than the one end portion of the first extended wire are located at the same height in the coil axial direction.

<58> The inductor component according to any one of <19> and <42> to <57>, in which the first coil wire and the first extended wire are connected at a corner portion corresponding to a portion where the first extended wire begins to extend obliquely from the linear portion of the first coil wire when viewed in the coil axial direction.

<59> The inductor component according to any one of <19> and <42> to <58>, in which the dimension of each of the one or the plurality of first extended wires in the coil axial direction is smaller than the dimension of each of the one or the plurality of second extended wires in the coil axial direction.

What is claimed is:

1. An inductor component comprising:
an element body;
a coil inside the element body and spirally wound along a coil axial direction;
a first outer electrode electrically connected to one end portion of the coil and exposed on a surface of the element body; and
a second outer electrode electrically connected to another end portion of the coil and exposed on the surface of the element body, wherein
the element body includes an insulator,
the coil includes a plurality of electrically connected coil wires laminated in the coil axial direction,
the plurality of coil wires include a first coil wire electrically connected to the first outer electrode with one or a plurality of first extended wires interposed therebetween, and
a dimension of each of the one or the plurality of first extended wires in the coil axial direction is smaller than a dimension of the first coil wire in the coil axial direction.

2. The inductor component according to claim 1, wherein
the first coil wire is electrically connected to the first outer electrode with the plurality of first extended wires arranged in the coil axial direction interposed therebetween.

3. The inductor component according to claim 2, wherein
the plurality of first extended wires each have an identical dimension in the coil axial direction.

4. The inductor component according to claim 2, wherein
the plurality of first extended wires include a first outer side portion extended wire and a first inner side portion extended wire located further inside the element body than the first outer side portion extended wire in the coil axial direction, and
a dimension of the first outer side portion extended wire in the coil axial direction and a dimension of the first inner side portion extended wire in the coil axial direction are different from each other.

5. The inductor component according to claim 4, wherein
the dimension of the first outer side portion extended wire in the coil axial direction is smaller than the dimension of the first inner side portion extended wire in the coil axial direction.

6. The inductor component according to claim 2, wherein
the plurality of first extended wires include three or more first extended wires, and
intervals between the plurality of first extended wires in the coil axial direction are same as each other.

7. The inductor component according to claim 2, wherein
the plurality of first extended wires include a first outer side portion extended wire, a first inner side portion extended wire located further inside the element body than the first outer side portion extended wire in the coil axial direction, and a first intermediate portion extended wire located between the first outer side portion extended wire and the first inner side portion extended wire and adjacent to both the first outer side portion extended wire and the first inner side portion extended wire in the coil axial direction, and
an interval between the first outer side portion extended wire and the first intermediate portion extended wire in the coil axial direction and an interval between the first inner side portion extended wire and the first intermediate portion extended wire in the coil axial direction are different from each other.

8. The inductor component according to claim 7, wherein
the interval between the first outer side portion extended wire and the first intermediate portion extended wire in the coil axial direction is larger than the interval between the first inner side portion extended wire and the first intermediate portion extended wire in the coil axial direction.

9. The inductor component according to claim 2, wherein
the plurality of first extended wires include a first outer side portion extended wire and a first inner side portion extended wire located further inside the element body than the first outer side portion extended wire in the coil axial direction,
when viewed in a length direction orthogonal to the coil axial direction, one end portion of the first coil wire and an end portion of the first outer side portion extended wire opposite to the first inner side portion extended wire are located at a same height in the coil axial direction, and
when viewed in the length direction, another end portion of the first coil wire located further inside the element body than the one end portion of the first coil wire and an end portion of the first inner side portion extended wire opposite to the first outer side portion extended wire are located at a same height in the coil axial direction.

10. The inductor component according to claim 1, wherein
the dimension of the first extended wire in the coil axial direction increases from a first outer electrode side toward a first coil wire side.

11. The inductor component according to claim 1, wherein
a number of the first extended wires increases from a first outer electrode side toward a first coil wire side.

12. The inductor component according to claim 1, wherein
when viewed in a length direction orthogonal to the coil axial direction, both end portions of the first extended wire and both end portions of the first outer electrode are displaced from each other in the coil axial direction.

13. The inductor component according to claim 12, wherein
when viewed in the length direction, one end portion of the first coil wire and one end portion of the first extended wire are located at different heights from each other in the coil axial direction, and
when viewed in the length direction, another end portion of the first coil wire located further inside the element body than the one end portion of the first coil wire and another end portion of the first extended wire located further inside the element body than the one end portion of the first extended wire are located at a same height in the coil axial direction.

14. The inductor component according to claim 1, wherein
the first coil wire and the first extended wire are connected at a corner portion corresponding to a portion where the first extended wire begins to extend obliquely from a linear portion of the first coil wire when viewed in the coil axial direction.

15. The inductor component according to claim 1, wherein
the surface of the element body includes a bottom surface parallel to the coil axial direction and a top surface facing the bottom surface in a height direction orthogonal to the coil axial direction, and
the first outer electrode and the second outer electrode are exposed and separated from each other at least on the bottom surface of the element body.

16. The inductor component according to claim 1, wherein
the surface of the element body includes a bottom surface perpendicular to the coil axial direction and a top surface facing the bottom surface in the coil axial direction, and
the first outer electrode and the second outer electrode are exposed and separated from each other at least on the bottom surface of the element body.

17. The inductor component according to claim 16, wherein
the plurality of coil wires further include a second coil wire electrically connected to the second outer electrode with one or a plurality of second extended wires interposed therebetween,
the first extended wire is located further toward a top surface side of the element body than the second extended wire in the coil axial direction, and
the dimension of each of the one or the plurality of first extended wires in the coil axial direction is smaller than a dimension of each of the one or the plurality of second extended wires in the coil axial direction.

18. The inductor component according to claim 2, wherein
the surface of the element body includes a bottom surface parallel to the coil axial direction and a top surface facing the bottom surface in a height direction orthogonal to the coil axial direction, and
the first outer electrode and the second outer electrode are exposed and separated from each other at least on the bottom surface of the element body.

19. An inductor component comprising:
an element body;
a coil inside the element body and spirally wound along a coil axial direction;
a first outer electrode electrically connected to one end portion of the coil and exposed on a surface of the element body; and
a second outer electrode electrically connected to another end portion of the coil and exposed on the surface of the element body, wherein
the element body includes an insulator,
the coil includes a plurality of electrically connected coil wires laminated in the coil axial direction,
the plurality of coil wires include a first coil wire electrically connected to the first outer electrode with one or a plurality of first extended wires interposed therebetween, and
when viewed in a length direction orthogonal to the coil axial direction, both end portions of the first extended wire and both end portions of the first outer electrode are displaced from each other in the coil axial direction.

20. An inductor component comprising:
an element body;
a coil inside the element body and spirally wound along a coil axial direction;
a first outer electrode electrically connected to one end portion of the coil and exposed on a surface of the element body; and
a second outer electrode electrically connected to another end portion of the coil and exposed on the surface of the element body, wherein
the element body includes an insulator,
the surface of the element body includes a bottom surface perpendicular to the coil axial direction and a top surface facing the bottom surface in the coil axial direction,
the first outer electrode and the second outer electrode are exposed and separated from each other at least on the bottom surface of the element body,
the coil includes a plurality of electrically connected coil wires laminated in the coil axial direction,
the plurality of coil wires include a first coil wire electrically connected to the first outer electrode with one or a plurality of first extended wires interposed therebetween and a second coil wire electrically connected to the second outer electrode with one or a plurality of second extended wires interposed therebetween,
the first extended wire is located further toward a top surface side of the element body than the second extended wire in the coil axial direction, and
when viewed in a length direction orthogonal to the coil axial direction, a minimum distance between an end portion of the first extended wire and an end portion of the first outer electrode is larger than a minimum distance between an end portion of the second extended wire and an end portion of the second outer electrode in a width direction orthogonal to the coil axial direction and to the length direction.
